(19) United States
(12) Patent Application Publication
(10) Pub. No.: US 2026/0244248 A1
(43) Pub. Date: Aug. 20, 2026

(54) DISPLAY DEVICE, METHOD OF MANUFACTURING THE DISPLAY DEVICE, AND ELECTRONIC DEVICE INCLUDING THE DISPLAY DEVICE

(71) Applicant: Samsung Display Co., Ltd., Yongin-si (KR)

(72) Inventors: Jihoon KIM, Yongin-si (KR); MIN-SUNG KIM, Yongin-si (KR); SUNGSANG AHN, Yongin-si (KR); Subon KIM, Yongin-si (KR)

(21) Appl. No.: 19/307,651

(22) Filed: Aug. 22, 2025

(30) Foreign Application Priority Data
Feb. 18, 2025 (KR) 10-2025-0020683

(51) Int. Cl. G06F 1/16; H10K 59/12; H10K 59/80; H10K 102/00

(52) U.S. Cl. CPC G06F 1/1681; G06F 1/1641; G06F 1/1656; H10K 59/1201; H10K 59/8722; H10K 2102/311; H10K 2102/351

(57) ABSTRACT

Provided is a display device including a display module including a folding region and a non-folding region adjacent to the folding region, a (1-1)-th support plate which is disposed below the display module, and in which first openings overlapping the folding region are defined, a (1-2)-th support plate which is disposed below the (1-1)-th support plate, and in which second openings overlapping the folding region are defined, and an adhesive layer disposed between the (1-1)-th support plate and the (1-2)-th support plate. The adhesive layer may include a first adhesive layer overlapping the folding region. The adhesive layer may include a second adhesive layer overlapping the non-folding region and having a rigidity which is different from a rigidity of the first adhesive layer.

### CROSS REFERENCE TO RELATED APPLICATION

This application claims priority to Korean Patent Application No. 10-2025-0020683, filed on February 18, 2025, and all the benefits accruing therefrom under 35 U.S.C. §119, the content of which in its entirety is herein incorporated by reference.

### BACKGROUND

### Field

The present disclosure herein relates to a display device, a method of manufacturing the display device, and an electronic device including the display device.

### Description of the Related Art

An electronic device which provides images to a user, such as a smart phone, a digital camera, a laptop computer, a navigation unit, and a smart television, includes a display device for displaying images. The display device generates images and provides the images to a user via a display screen.

Recently, with the technological development of display devices, various types of display devices have been developed. For example, a variety of flexible display devices, which are deformable into a curved form, foldable, or rollable, are being developed. Flexible display devices having diversely deformable shapes are easy to carry and improve user convenience.

A folding display device among the flexible display devices includes a display module which is folded with respect to a folding axis extending in one direction. The display module is folded or unfolded with respect to the folding axis. The display module includes a folding region which bends during a folding operation. The folding region may be bent to have a predetermined radius of curvature.

The folding display device includes a support plate which is disposed below the display module and supports the display module. The support plate is folded with the display module. Development of a technology for a support plate which has a high rigidity, is easily folded with the display module, and is lightweight is desired.

### SUMMARY

The present disclosure provides a display device including a support plate, which has a high rigidity, is easily folded with a display module, and is lightweight, a method of manufacturing the display device, and an electronic device including the display device.

An embodiment of the inventive concept provides a display device including: a display module including a folding region and a non-folding region adjacent to the folding region; a (1-1)-th support plate which is disposed below the display module, and in which first openings overlapping the folding region are defined; a (1-2)-th support plate which is disposed below the (1-1)-th support plate, and in which second openings overlapping the folding region are defined; and an adhesive layer disposed between the (1-1)-th support plate and the (1-2)-th support plate. The adhesive layer includes a first adhesive layer overlapping the folding region, and a second adhesive layer overlapping the non-folding region and having a rigidity which is different from a rigidity of the first adhesive layer.

In an embodiment of the inventive concept, a method of manufacturing a display device includes: preparing a (1-1)-th support plate in which first openings are defined; providing, below the (1-1)-th support plate, a (1-2)-th support plate in which second openings overlapping the first openings are defined; providing an adhesive layer between the (1-1)-th support plate and the (1-2)-th support plate; forming a first adhesive layer overlapping the first openings and the second openings and a second adhesive layer not overlapping the first openings and the second openings, wherein each of the first adhesive layer and the second adhesive layer is defined as a respective portion of the adhesive layer, and a rigidity of the first adhesive layer is different from a rigidity of the second adhesive layer; and providing, on the (1-1)-th support plate, a display module which includes a folding region overlapping the first adhesive layer and a non-folding region adjacent to the folding region and overlapping the second adhesive layer.

In an embodiment of the inventive concept, an electronic device includes: a processor; and a display device which receives an image signal from the processor and provide, to a user, an image corresponding to the image signal, wherein the display device includes a display module including a folding region and a non-folding region adjacent to the folding region, a (1-1)-th support plate which is disposed below the display module, and in which first openings overlapping the folding region are defined, a (1-2)-th support plate which is disposed below the (1-1)-th support plate, and in which second openings overlapping the folding region are defined; and an adhesive layer disposed between the (1-1)-th support plate and the (1-2)-th support plate, and the adhesive layer includes a first adhesive layer overlapping the folding region, and a second adhesive layer overlapping the non-folding region, wherein the first adhesive layer has a modulus which is smaller than a modulus of the second adhesive layer.

### BRIEF DESCRIPTION OF THE DRAWINGS

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a block diagram of an electronic device according to an embodiment of the inventive concept;

FIG. 2 is a schematic view of each of electronic devices according to various embodiments;

FIG. 3 is a perspective view of an electronic device according to an embodiment of the inventive concept;

FIG. 4 is a view illustrating a state in which the electronic device illustrated in FIG. 3 is folded;

FIG. 5 is a perspective view of an electronic device according to another embodiment of the inventive concept;

FIG. 6 is a view illustrating a state in which the electronic device illustrated in FIG. 5 is folded;

FIG. 7 is an exploded perspective view of the electronic device illustrated in FIG. 3;

FIG. 8 is a plan view of a display panel used for a display device illustrated in FIG. 7;

FIG. 9 exemplarily illustrates a cross-sectional view of a display panel illustrated in FIG. 8;

FIG. 10 illustrates, in more detail, a cross-sectional view of a display panel corresponding to one pixel illustrated in FIG. 8;

FIG. 11 is a cross-sectional view of a display device taken along line I-I' described in FIG. 8;

FIG. 12 is a cross-sectional view taken along line II-II' described in FIG. 8;

FIG. 13 is a perspective view of a support plate illustrated in FIG. 11;

FIG. 14 is an enlarged plan view of a region AA illustrated in FIG. 13;

FIG. 15 is a view illustrating a state in which the display device illustrated in FIG. 11 is folded;

FIG. 16 is a view illustrating a display module and a first support plate illustrated in FIG. 11;

FIGS. 17A to 17D are views describing a method of manufacturing a display device according to an embodiment of the inventive concept;

FIGS. 18A to 18D are views describing a method of manufacturing a display device according to another embodiment of the inventive concept;

FIG. 19 is a view illustrating a configuration of a first adhesive layer according to another embodiment of the inventive concept;

FIGS. 20A to 20C are views describing a method of manufacturing a display device according to another embodiment of the inventive concept;

FIG. 21 is a view illustrating a configuration of an adhesive layer according to another embodiment of the inventive concept;

FIG. 22 is a view describing a curing process of an adhesive layer according to another embodiment of the inventive concept; and

FIG. 23 is an exploded view illustrating a (1-1)-th support plate, a (1-2)-th support plate, and an adhesive layer illustrated in FIG. 22.

### DETAILED DESCRIPTION

In this specification, it will be understood that when an element (or a region, a layer, a portion, or the like) is referred to as being "on", "connected to" or "coupled to" another element, it may be directly disposed on/connected to/coupled to the other element, or other elements may be disposed therebetween.

Like reference numerals or symbols refer to like elements throughout. In the drawings, the thickness, ratio, and size of the elements are exaggerated for effectively describing the technical contents. As used herein, the term "and/or" includes any and all combinations of one or more of the associated listed elements.

It will be understood that, although the terms “first”, “second”, and the like may be used herein to describe various elements, the elements are not to be limited by these terms. These terms are used to distinguish one element, component, region, layer or section from another element, component, region, layer or section. For instance, a first element, component, region, layer or section discussed below could be termed a second element, component, region, layer or section without departing from the scope of the inventive concept. Similarly, a second element, component, region, layer or section could be termed a first element, component, region, layer or section. In this specification, the singular expressions "a", "an" and "the" are intended to include the plural forms as well, unless the context clearly indicates otherwise.

The terms "below", “under”, "on the lower side", "above", “over”, "on the upper side", or the like may be used to describe the relationships between the elements illustrated in the drawings. These terms are relative concepts and are described on the basis of the directions indicated in the drawings.

It will be further understood that the terms "comprises, includes, has" and/or "comprising, including, having", when used in this specification, specify the presence of stated features, numbers, steps, operations, elements, components or combinations thereof, but do not preclude the possibility of the presence or addition of one or more other features, numbers, steps, operations, elements, components, and/or combinations thereof.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within ± 30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the inventive concept are described with reference to the drawings.

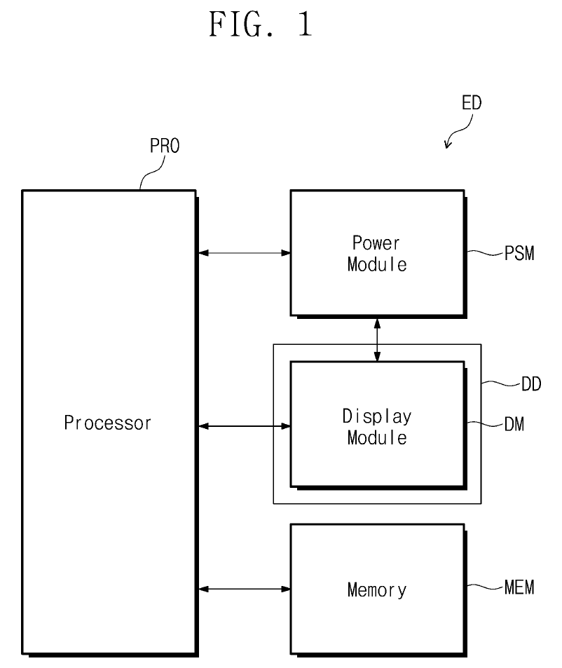

FIG. 1 is a block diagram of an electronic device according to an embodiment of the inventive concept.

Referring to FIG. 1, an electronic device ED according to an embodiment may include a display device DD which provides images to a user, and further include a module or a device which has additional functions in addition to the display device DD. The electronic device ED according to an embodiment may include a display module DM, a processor PRO, a memory MEM, and a power module PSM, and the display device DD may include the display module DM.

The processor PRO may include at least one of a central processing unit (CPU), an application processor (AP), a graphic processing unit (GPU), a communication processor (CP), an image signal processor (ISP), or a controller.

The processor PRO may process image signals and provide the processed image signals to the display device DD. The display device DD may receive the image signals from the processor PRO and provide images corresponding to the image signals to a user.

The processor PRO may be electrically connected to the display module DM of the display device DD via a flexible circuit board, a connector, or the like. The display module DM may display an image on the basis of data received from the processor PRO.

In an embodiment, the processor PRO may be provided to be divided into two or more parts from a functional or structural viewpoint. For example, the processor PRO may include a main processor in a form of a first driver chip including a central processing unit, and an auxiliary processor in a form of a second driver chip including a controller which receives image signals from the main processor and processes the image signals so as to be suitable for an interface specification for the display module DM.

The memory MEM may store data information for an operation of the processor PRO or the display module DM. In an example in which the processor PRO executes an application stored in the memory MEM, image signals and/or input control signals are transmitted to the display module DM, and the display module DM may process the provided image signals and output image information through a display screen.

The power module PSM may include a power supply module, such as a power adapter or a battery device, and a power conversion module which converts a power supplied by the power supply module to generate a power for an operation of the electronic device ED.

At least one of components of the above-described electronic device ED may be included in the display device DD according to the above-described embodiments. In some aspects, some of the individual modules which are functionally included in one module may be included in the display device DD, and other modules may also be provided separately from the display device DD. For example, the display device DD may include the display module DM, and the processor PRO, the memory MEM, and the power module PSM may be provided in a form of other devices within the electronic device ED other than the display device DD.

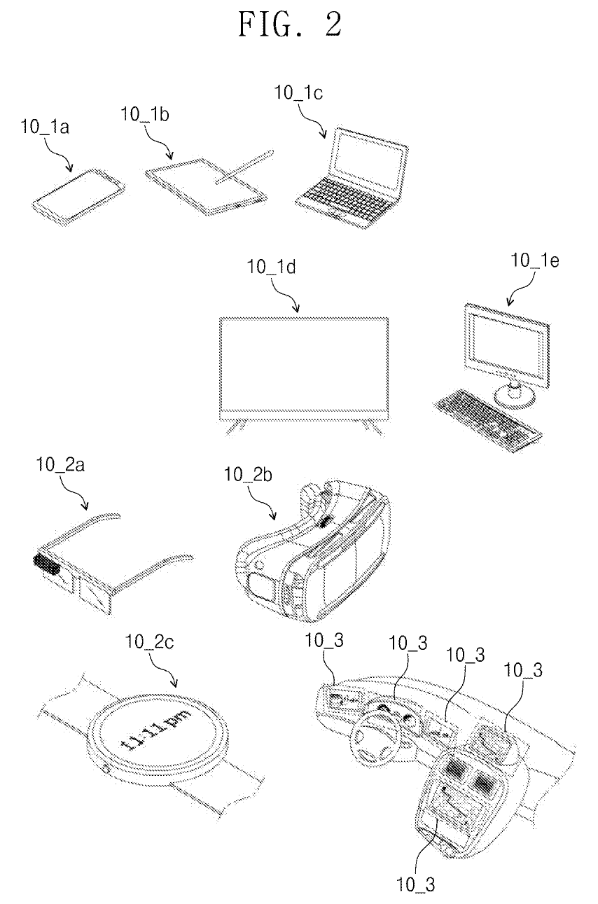

FIG. 2 is a schematic view of each of electronic devices according to various embodiments.

Referring to FIG. 2, a display device DD according to an embodiment of the inventive concept may be applied to various electronic devices. For example, the various electronic devices applied with the display device DD according to an embodiment may include electronic devices for displaying images, such as a smart phone 10_1a, a tablet computer 10_1b, a laptop computer 10_1c, a television 10_1d, or a desktop monitor 10_1e.

In some aspects, the various electronic devices applied with the display device DD according to an embodiment may include wearable electronic devices, such as a smart glasses 10_2a, a head mounted display 10_2b, or a smart watch 10_2c. Furthermore, the various electronic devices applied with the display device DD according to an embodiment may include automobile electronic devices 10_3 such as a center information display (CID) disposed on an instrument panel, a center fascia, or a dashboard of a car, and a room mirror display.

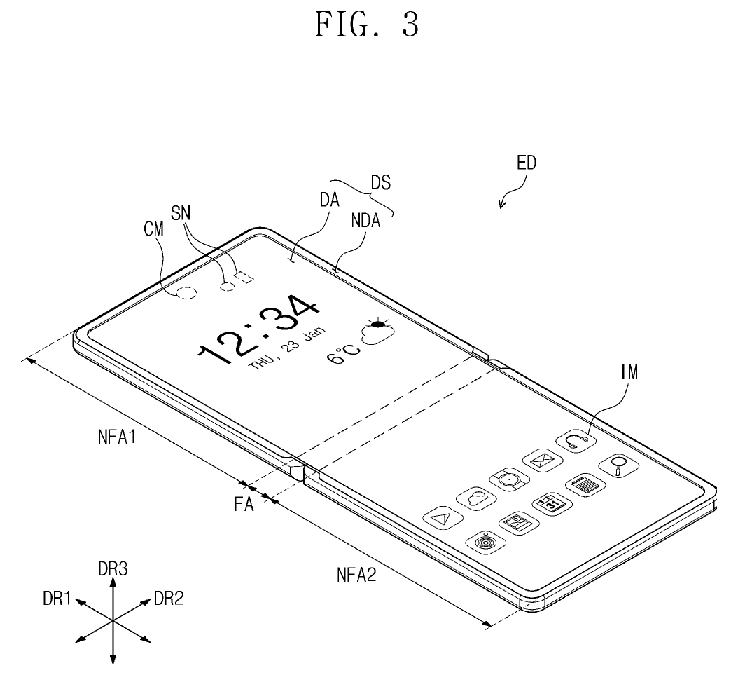

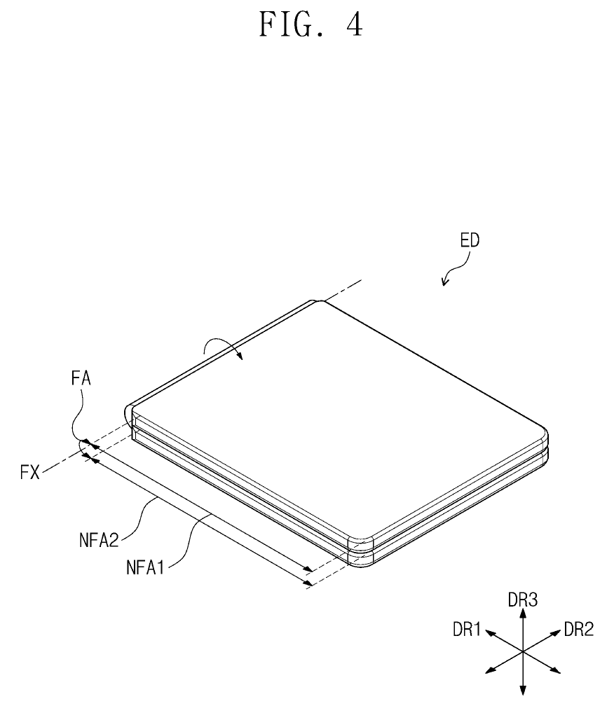

FIG. 3 is a perspective view of an electronic device according to an embodiment of the inventive concept. FIG. 4 is a view illustrating a state in which the electronic device illustrated in FIG. 3 is folded.

Referring to FIG. 3, an electronic device ED according to an embodiment of the inventive concept may have long sides extending in a first direction DR1 and short sides extending in a second direction DR2 crossing the first direction DR1.

Hereinafter, a direction, which is substantially perpendicular to a plane defined by the first direction DR1 and the second direction DR2, is defined as a third direction DR3. In this specification, the wording “when viewed on a plane” may be defined as a state when viewed in the third direction DR3. In this specification, the wording “overlapping” may be referred to as a state in which components are disposed such that the components overlap each other when viewed on a plane.

The electronic device ED may include a folding region FA, and a plurality of non-folding regions NFA1 and NFA2 adjacent to the folding region FA. The non-folding regions NFA1 and NFA2 may include a first non-folding region NFA1 and a second non-folding region NFA2. The folding region FA may be disposed between the first non-folding region NFA1 and the second non-folding region NFA2. The first non-folding region NFA1, the folding region FA, and the second non-folding region NFA2 may be arranged in the first direction DR1.

One folding region FA and two non-folding regions NFA1 and NFA2 are illustrated as examples, but the number of the folding region FA and the number of the non-folding regions NFA1 and NFA2 are not limited thereto. For example, the display device DD may include more than two non-folding regions and a plurality of folding regions disposed between the non-folding regions.

An upper surface of the folding region FA may be defined as a display surface DS and have a flat surface defined by the first direction DR1 and the second direction DR2. Images IM generated from the folding region FA may be provided to users through the display surface DS.

The display surface DS may include a display region DA and a non-display region NDA around the display region DA. The display region DA may display images, and the non-display region NDA may not display images. The non-display region NDA may surround the display region DA and define a border of the folding region FA printed in a predetermined color.

The folding region FA may include a plurality of sensors SN and at least one camera CM. The sensors SN and the camera CM may be adjacent to the border of the folding region FA. The sensors SN and the camera CM may be disposed in the display region DA adjacent to the non-display region NDA. The sensors SN and the camera CM may be disposed in the first non-folding region NFA1, but arrangement positions at which the sensors SN and the camera CM are disposed are not limited thereto.

For example, the sensors SN may include proximity luminance sensors, but types of the sensors SN are not limited thereto. The camera CM may capture an external image.

Referring to FIGS. 3 and 4, the electronic device ED may be a flexible electronic device. For example, the electronic device ED may be a folding-type (foldable) electronic device which is folded or unfolded. For example, the electronic device ED may be folded such that the folding region FA is bent with respect to a folding axis FX parallel to the second direction DR2. The folding axis FX may be defined as a short axis parallel to a short side of the electronic device ED.

When the electronic device ED is folded, the electronic device ED may be in-folded such that the first non-folding region NFA1 and the second non-folding region NFA2 face each other and the display surface DS is not exposed to the outside. However, embodiments of the present disclosure are not limited thereto. For example, the electronic device ED may also be out-folded with respect to the folding axis FX such that the display surface DS is exposed to the outside.

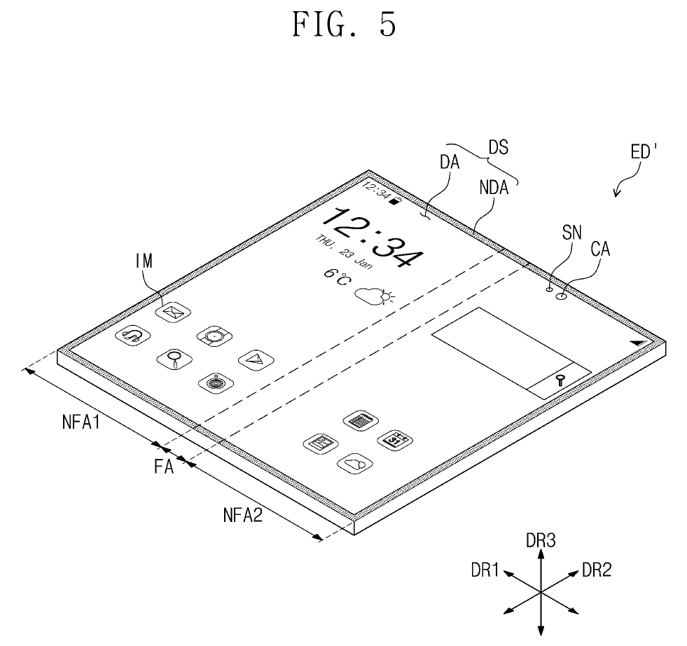

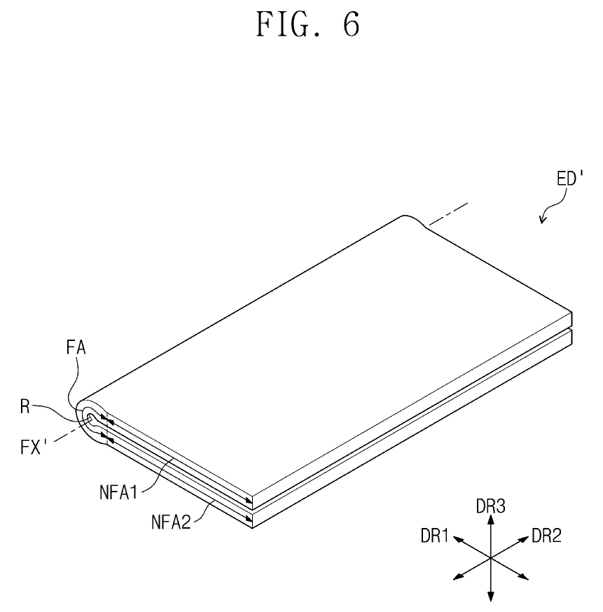

FIG. 5 is a perspective view of an electronic device according to another embodiment of the inventive concept. FIG. 6 is a view illustrating a state in which the electronic device illustrated in FIG. 5 is folded.

Referring to FIGS. 5 and 6, an electronic device ED’ may have short sides extending in the first direction DR1 and long sides extending in the second direction DR2. The electronic device ED’ may be a foldable device. For example, the electronic device ED’ may be folded such that a folding region FA is bent with respect to a folding axis FX’ parallel to the second direction DR2. The folding axis FX’ may be defined as a short axis parallel to a long side of the electronic device ED’. Other components of the electronic device ED’ may be the substantially same as those of the electronic device ED illustrated in FIGS. 3 and 4.

When the electronic device ED’ is folded, a distance between the first non-folding region NFA1 and the second non-folding region NFA2 may be smaller than a diameter of a circle defined by a curvature radius R of the folding region FA. In this case, the folding region FA may be folded in a dumbbell-like shape, and the distance between the first non-folding region NFA1 and the second non-folding region NFA2 may become even shorter.

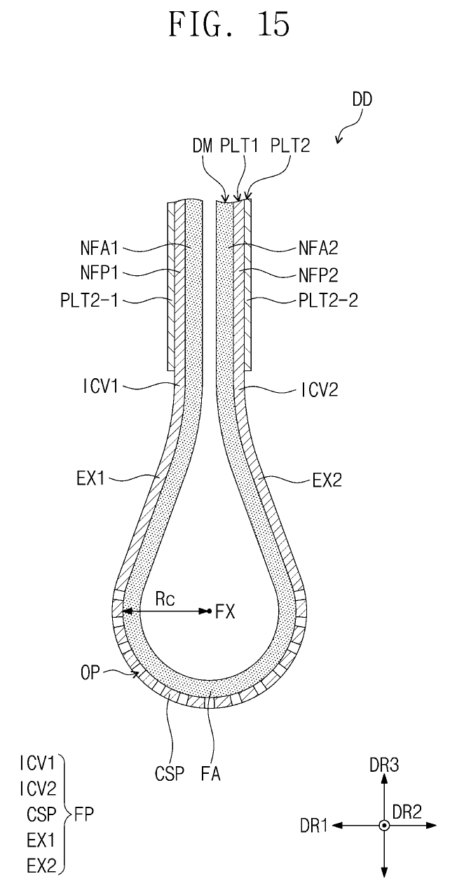

Although not illustrated in FIG. 4, the electronic device ED may also be folded in a dumbbell-like shape such as the electronic device ED’, and the shape will be illustrated below in FIG. 15.

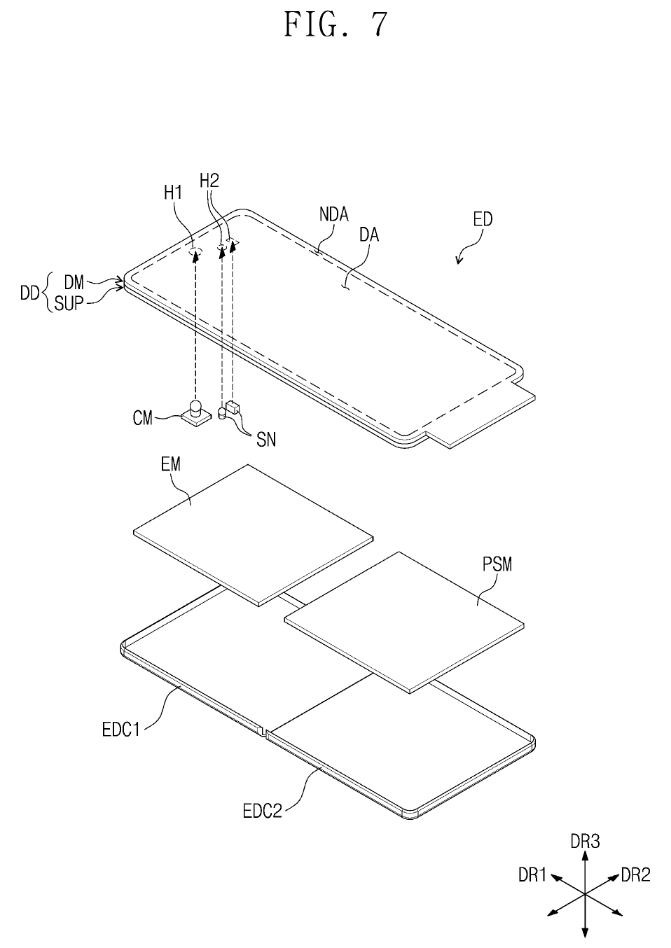

FIG. 7 is an exploded perspective view of the electronic device illustrated in FIG. 3.

Referring to FIG. 7, an electronic device ED may include a display device DD, a camera CM, sensors SN, an electronic module EM, a power module PSM, and cases EDC1 and EDC2. A first hole H1 and second holes H2 may be defined in the display device DD, the camera CM may be disposed in the first hole H1, and the sensors SN may be disposed in the second holes H2. The configurations of the first hole H1 and the second holes H2 will be described herein in detail with reference to FIG. 12.

The electronic module EM and the power module PSM may be disposed below the display device DD. Although not illustrated, the electronic module EM and the power module PSM may be connected to each other via a flexible circuit board. The electronic module EM may control an operation of a display module DM. The power module PSM may supply power to the display module DM. The electronic module EM may include the above-described processor PRO.

The cases EDC1 and EDC2 may accommodate the display device DD, the camera CM, the sensors SN, the electronic module EM, and the power module PSM. The cases EDC1 and EDC2 may protect the display device DD, the camera CM, the sensors SN, the electronic module EM, and the power module PSM.

The cases EDC1 and EDC2 may include a first case EDC1 and a second case EDC2 disposed in the first direction DR1 so as to allow the display device DD to be folded. The first case EDC1 may overlap the above-described first non-folding region NFA1, and the second case EDC2 may overlap the above-described second non-folding region NFA2.

Although not illustrated, the electronic device ED may further include a hinge structure which is connected to the first case EDC1 and the second case EDC2 and controls a folding operation of the electronic device ED.

The display device DD may include the display module DM, and a support part SUP disposed below the display module DM. The display module DM and the support part SUP may be accommodated in the cases EDC1 and EDC2. The components of the display module DM and the support part SUP will be described herein in detail.

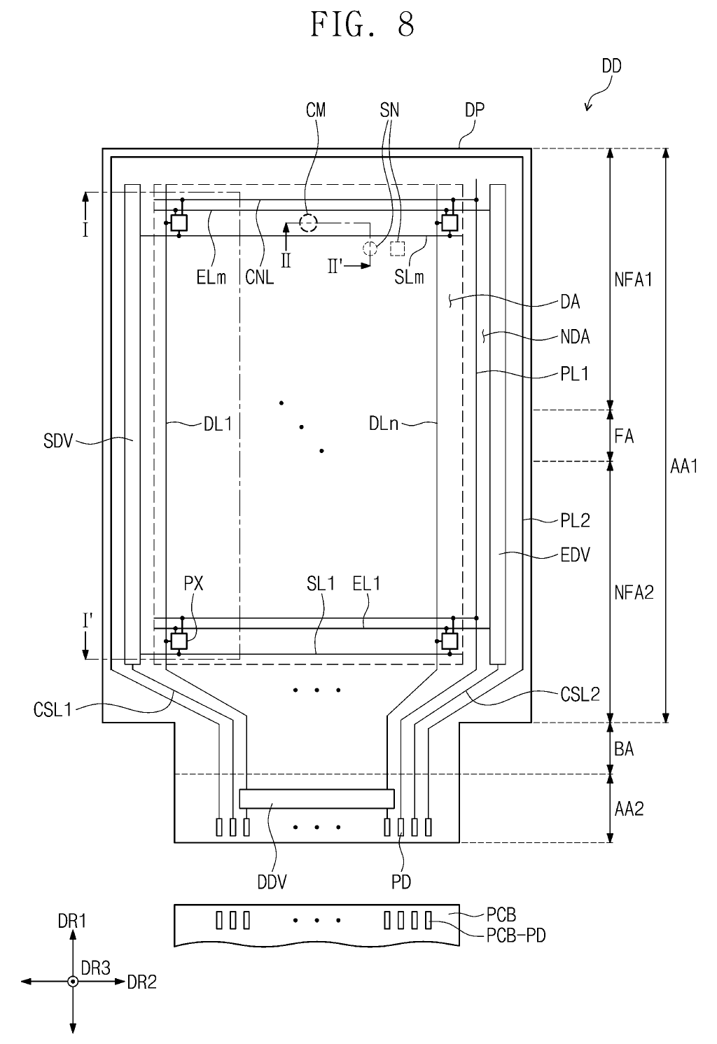

FIG. 8 is a plan view of a display panel used for a display device illustrated in FIG. 7.

A display panel DP illustrated in FIG. 8 may be included in a display module DM.

Referring to FIG. 8, a display device DD may include a display panel DP, a scan driver SDV, a data driver DDV, and an emission driver EDV.

The display panel DP according to an embodiment of the inventive concept may be a light-emitting display panel. For example, the display panel DP may be an organic light-emitting display panel or an inorganic light-emitting display panel. A light-emitting layer of the organic light-emitting display panel may include organic light-emitting materials. A light-emitting layer of the inorganic light-emitting display panel may include quantum dots, quantum rods, or the like. Hereinafter, the display panel DP is described as an organic light-emitting display panel.

The display panel DP may be a flexible display panel. The display panel DP may extend longer in the first direction DR1 than in the second direction DR2. The display panel DP may include a first region AA1, a second region AA2, and a bending region BA disposed between the first region AA1 and the second region AA2. The bending region BA may extend in the second direction DR2, and the first region AA1, the bending region BA, and the second region AA2 may be arranged in the first direction DR1.

The first region AA1 may have long sides which extend in the first direction DR1 and are opposite to each other in the second direction DR2. The lengths of the bending region BA and the second region AA2 may be smaller than the length of the first region AA1 with respect to the second direction DR2.

The first region AA1 may include a display region DA and a non-display region NDA around the display region DA. The non-display region NDA may surround the display region DA. The display region DA may be defined as a region which displays images, and the non-display region NDA may be defined as a region which does not display images. The second region AA2 and the bending region BA may be defined as regions which do not display images. The sensors SN and the camera CM may be disposed in the display region DA.

The first region AA1 may include a folding region FA and first and second non-folding regions NFA1 and NFA2 adjacent to the folding region FA when viewed in the second direction DR2. The folding region FA and the first and second non-folding regions NFA1 and NFA2 of the display panel DP may correspond to the folding region FA and the first and second non-folding regions NFA1 and NFA2 of the above-described electronic device ED. Accordingly, the folding region FA may be disposed between the first non-folding region NFA1 and the second non-folding region NFA2, and the first non-folding region NFA1, the folding region FA, and the second non-folding region NFA2 may be arranged in the first direction DR1.

The display panel DP may include a plurality of pixels PX, a plurality of scan lines SL1 to SLm, a plurality of data lines DL1 to DLn, a plurality of emission lines EL1 to ELm, first and second control lines CSL1 and CSL2, a first power line PL1, a second power line PL2, a plurality of connection lines CNL, and a plurality of pads PD. m and n are natural numbers. The pixels PX may be disposed in the display region DA, and be connected to the scan lines SL1 to SLm, the data lines DL1 to DLn, and the emission lines EL1 to ELm.

The scan driver SDV and the emission driver EDV may be disposed in the non-display region NDA. The scan driver SDV and the emission driver EDV may be disposed in the non-display region NDA adjacent to the respective long sides of the first region AA1. The data driver DDV may be disposed in the second region AA2. The data driver DDV may be manufactured in a form of an integrated circuit chip and be mounted on the second region AA2.

Although not illustrated, the bending region BA may be bent, and the second region AA2 may be disposed below the first region AA1. In this case, the data driver DDV is disposed below the first region AA1, and may thus be invisible from the outside.

The scan lines SL1 to SLm may extend in the second direction DR2 to be connected to the scan driver SDV. The data lines DL1 to DLn may extend in the first direction DR1 to be connected to the data driver DDV via the bending region BA. The emission lines EL1 to ELm may extend in the second direction DR2 to be connected to the emission driver EDV.

The first power line PL1 may extend in the first direction DR1 and be disposed in the non-display region NDA. The first power line PL1 may be disposed between the display region DA and the emission driver EDV. However, embodiments of the present disclosure are not limited thereto, and the first power line PL1 may also be disposed between the display region DA and the scan driver SDV.

The first power line PL1 may extend to the second region AA2 via the bending region BA. The first power line PL1 may extend toward a lower end of the second region AA2 when viewed on a plane. The first power line PL1 may receive a first voltage.

The second power line PL2 may be disposed both in the non-display region NDA adjacent to long sides of the first region AA1 and in the non-display region NDA facing the second region AA2 with the display region DA between the first region AA1 and in the non-display region NDA. The second power line PL2 may be disposed further outside than the scan driver SDV and the emission driver EDV.

The second power line PL2 may extend to the second region AA2 via the bending region BA. In the second region AA2, the second power line PL2 may extend in the first direction DR1 with the data driver DDV between the second power lines PL2. The second power line PL2 may extend toward a lower end of the second region AA2 when viewed on a plane.

The second power line PL2 may receive a second voltage having a voltage level lower than the first voltage. Although the connection relationship is not illustrated for convenience of description, the second power line PL2 may extend to the display region DA to be connected to the pixels PX, and the second voltage may be supplied to the pixels PX via the second power line PL2.

Connection lines CNL may extend in the second direction DR2 and be arranged in the first direction DR1. The connection lines CNL may be connected to the first power line PL1 and the pixels PX. The first voltage may be applied to the pixels PX via the first power line PL1 and the connection lines CNL which are connected to each other.

The first control line CSL1 may be connected to the scan driver SDV and extend toward the lower end of the second region AA2 via the bending region BA. The second control line CSL2 may be connected to the emission driver EDV and extend toward the lower end of the second region AA2 via the bending region BA. The data driver DDV may be disposed between the first control line CSL1 and the second control line CSL2.

When viewed on a plane, the pads PD may be disposed adjacent to the lower end of the second region AA2. The data driver DDV, the first power line PL1, the second power line PL2, the first control line CSL1, and the second control line CSL2 may be connected to the pads PD.

The data lines DL1 to DLn may be connected to corresponding pads PD via the data driver DDV. For example, the data lines DL1 to DLn may be connected to the data driver DDV, and the data driver DDV may be connected to the pads PD which respectively correspond to the data lines DL1 to DLn.

The display device DD may include a printed circuit board PCB connected to the pads PD. Connection pads PCB-PD may be disposed on the printed circuit board PCB, and the connection pads PCB-PD may be connected to the pads PD.

A timing controller (not illustrated) may be disposed on the printed circuit board PCB. The timing controller may be connected to the pads PD via the printed circuit board. The timing controller may control operations of the scan driver SDV, the data driver DDV, and the emission driver EDV. The timing controller may generate a scan control signal, a data control signal, and an emission control signal in response to control signals received from the outside.

The scan control signal may be provided to the scan driver SDV via the first control line CSL1. The emission control signal may be provided to the emission driver EDV via the second control line CSL2. The data control signal may be provided to the data driver DDV. The timing controller may receive image signals from the outside, convert data formats of the image signals to be suitable for interface specifications of the data driver DDV, and provide the converted signals to the data driver DDV.

The scan driver SDV may generate a plurality of scan signals in response to a scan control signal. The scan signals may be applied to the pixels PX via the scan lines SL1 to SLm. The scan signals may be sequentially applied to the pixels PX.

The data driver DDV may generate a plurality of data voltages corresponding to image signals in response to a data control signal. The data voltages may be applied to the pixels PX via the data lines DL1 to DLn. The emission driver EDV may generate a plurality of emission signals in response to an emission control signal. The emission signals may be applied to the pixels PX via the emission lines EL1 to ELm.

The pixels PX may receive data voltages in response to the scan signals. The pixels PX may display images by emitting light having a luminance corresponding to the data voltages in response to the emission signals. An emission time of the pixels PX may be controlled by the emission signals.

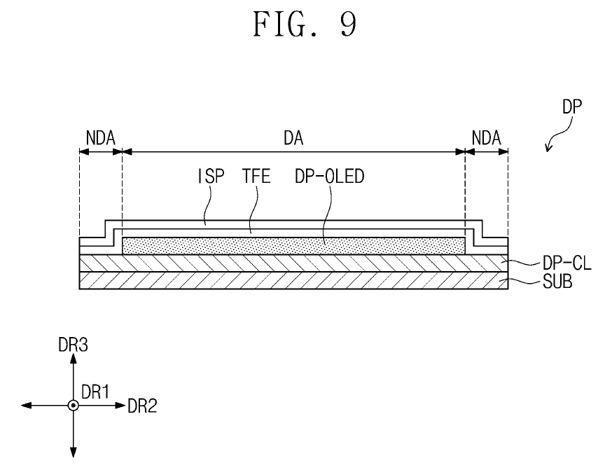

FIG. 9 exemplarily illustrates a cross-sectional view of the display panel illustrated in FIG. 8.

For example, FIG. 9 illustrates a cross section of a display panel DP when viewed in the first direction DR1.

Referring to FIG. 9, the display panel DP may include a substrate SUB, a circuit element layer DP-CL disposed on the substrate SUB, a display element layer DP-OLED disposed on the circuit element layer DP-CL, a thin-film encapsulation layer TFE disposed on the display element layer DP-OLED, and an input-sensing unit ISP disposed on the thin-film encapsulation layer TFE. The display element layer DP-OLED may be disposed on the display region DA.

The substrate SUB may include a display region DA and a non-display region NDA around the display region DA. The substrate SUB may include a flexible plastic material. For example, the substrate SUB may include polyimide (PI).

The circuit element layer DP-CL may include transistors. The display element layer DP-OLED may include light-emitting elements connected to the transistors. The pixels PX illustrated in FIG. 3 may include the transistors and the light-emitting elements.

The thin-film encapsulation layer TFE may be disposed on the circuit element layer DP-CL and cover the display element layer DP-OLED. The thin-film encapsulation layer TFE may include an inorganic layer, an organic layer, and an inorganic layer which are sequentially stacked. The inorganic layer may include an inorganic material and protect pixels from moisture/oxygen. The organic layer may include an organic material and protect the pixels PX against foreign substances such as dust particles.

The input-sensing unit ISP may include a plurality of sensors (not illustrated) for sensing an external input. The sensors may sense the external input in a capacitive method. The external input may include various types of inputs such as a portion of the user's body, light, heat, a pen, or pressure.

The input-sensing unit ISP may be manufactured directly on the thin-film encapsulation layer TFE when the display panel DP is manufactured. However, embodiments of the present disclosure are not limited thereto. The input-sensing unit ISP is manufactured as a panel separately from the display panel DP, and then may also be attached to the display panel DP via an adhesive layer.

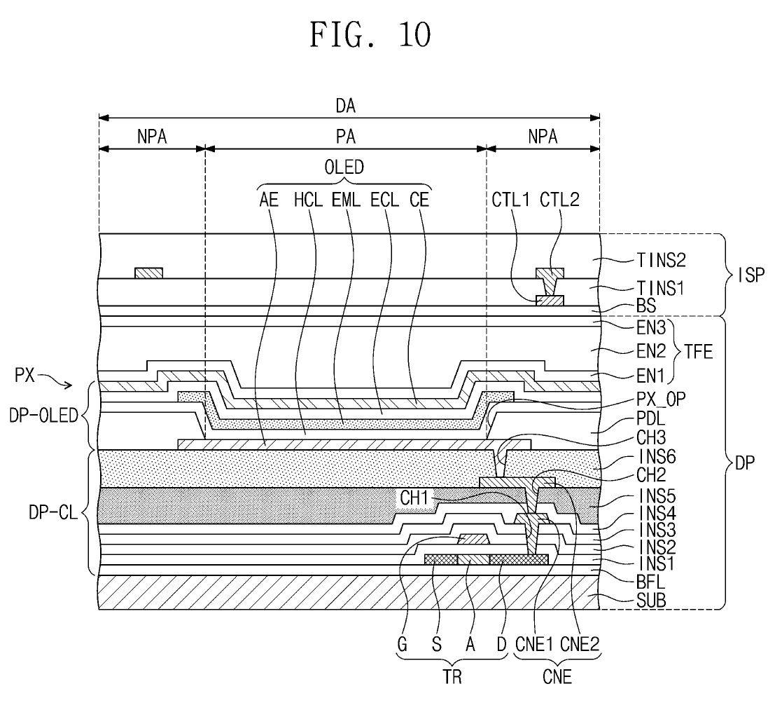

FIG. 10 illustrates, in more detail, a cross-sectional view of a display panel corresponding to one pixel illustrated in FIG. 8.

Referring to FIG. 10, a display panel DP may include a pixel PX, and the pixel PX may include a transistor TR and a light-emitting element OLED. The light-emitting element OLED may be an organic light-emitting element. The light-emitting element OLED may include a first electrode AE (or an anode), a second electrode CE (or a cathode), a hole control layer HCL, an electron control layer ECL, and a light-emitting layer EML.

The transistor TR and the light-emitting element OLED may be disposed on a substrate SUB. One transistor TR is exemplarily illustrated in the drawing, but substantially, the pixel PX may include a plurality of transistors and at least one capacitor for driving the light-emitting element OLED.

The display region DA may include a light-emitting region PA corresponding to each of the pixels PX, and a non-light-emitting region NPA around the light-emitting region PA. The light-emitting element OLED may be disposed in the light-emitting region PA.

A buffer layer BFL may be disposed on the substrate SUB, and the buffer layer BFL may be an inorganic layer. A semiconductor pattern may be disposed on the buffer layer BFL. The semiconductor pattern may include polysilicon, amorphous silicon, or metal oxide.

The semiconductor pattern may be doped with an N-type dopant or a P-type dopant. The semiconductor pattern may include a highly-doped region and a lightly-doped region. The highly-doped region may have a higher conductivity than the lightly-doped region, and substantially serve as a source electrode and a drain electrode of the transistor TR. The lightly-doped region may substantially correspond to an active (or a channel) of the transistor.

A source S, an active A, and a drain D of the transistor TR may be provided from the semiconductor pattern. A first insulating layer INS1 may be disposed on the semiconductor pattern. A gate G of the transistor TR may be disposed on the first insulating layer INS1. A second insulating layer INS2 may be disposed on the gate G. A third insulating layer INS3 may be disposed on the second insulating layer INS2.

A connection electrode CNE may include a first connection electrode CNE1 and a second connection electrode CNE2 for connecting the transistor TR and the light-emitting element OLED. The first connection electrode CNE1 may be disposed on the third insulating layer INS3 and be connected to the drain D via a first contact hole CH1 defined in the first to third insulating layers INS1 to INS3.

A fourth insulating layer INS4 may be disposed on the first connection electrode CNE1. A fifth insulating layer INS5 may be disposed on the fourth insulating layer INS4. A second connection electrode CNE2 may be disposed on the fifth insulating layer INS5. The second connection electrode CNE2 may be connected to the first connection electrode CNE1 via a second contact hole CH2 defined in the fourth and fifth insulating layers INS4 and INS5.

A sixth insulating layer INS6 may be disposed on the second connection electrode CNE2. The layers ranging from the buffer layer BFL to the sixth insulating layer INS6 may be defined as a circuit element layer DP-CL. The first insulating layer INS1 to the sixth insulating layer INS6 may each be an inorganic layer or an organic layer.

The first electrode AE may be disposed on the sixth insulating layer INS6. The first electrode AE may be connected to the second connection electrode CNE2 via a third contact hole CH3 defined in the sixth insulating layer INS6. A pixel-defining film PDL, in which an opening PX_OP for exposing a predetermined portion of the first electrode AE is defined, may be disposed on the first electrode AE and the sixth insulating layer INS6.

The hole control layer HCL may be disposed on the first electrode AE and the pixel-defining film PDL. The hole control layer HCL may include a hole transport layer and a hole injection layer.

The light-emitting layer EML may be disposed on the hole control layer HCL. The light-emitting layer EML may be disposed in a region corresponding to the opening PX_OP. The light-emitting layer EML may include an organic material and/or an inorganic material. The light-emitting layer EML may generate light having one color of red, green, or blue.

The electron control layer ECL may be disposed on the light-emitting layer EML and the hole control layer HCL. The electron control layer ECL may include an electron transport layer and an electron injection layer. The hole control layer HCL and the electron control layer ECL may be disposed in the light-emitting region PA and the non-light-emitting region NPA in common.

The second electrode CE may be disposed on the electron control layer ECL. The second electrode CE may be disposed in the pixels PX in common. The layer, on which the light-emitting element OLED is disposed, may be defined as a display element layer DP-OLED.

A thin-film encapsulation layer TFE may be disposed on the second electrode CE and cover the pixels PX. The thin-film encapsulation layer TFE may include a first encapsulation layer EN1 disposed on the second electrode CE and a second encapsulation layer EN2 disposed on the first encapsulation layer EN1, and a third encapsulation layer EN3 disposed on the second encapsulation layer EN2.

The first and third encapsulation layers EN1 and EN3 may include an inorganic insulating layer, and protect the pixels PX against moisture/oxygen. The second encapsulation layer EN2 may include an organic insulating layer and protect the pixels PX against foreign substances such as dust particles.

The first voltage may be applied to the first electrode AE via a transistor TR, and the second voltage having a lower voltage level than the first voltage may be applied to the second electrode CE. Holes and electrons injected into the light-emitting layer EML are combined to form excitons, and the excitons transition to a ground state, such that the light-emitting element OLED may emit light.

The layers, ranging from the substrate SUB to the thin-film encapsulation layer TFE, may be defined as the display panel DP. An input-sensing unit ISP may be disposed on the thin-film encapsulation layer TFE. The input-sensing unit ISP may be manufactured directly on an upper surface of the thin-film encapsulation layer TFE.

A base layer BS may be disposed on the thin-film encapsulation layer TFE. The base layer BS may include an inorganic insulating layer. At least one inorganic insulating layer may be provided on the thin-film encapsulation layer TFE as the base layer BS.

The input-sensing unit ISP may include a first conductive pattern CTL1 and a second conductive pattern CTL2 disposed on the first conductive pattern CTL1. The first conductive pattern CTL1 may be disposed on the base layer BS. A first insulating layer TINS1 may be disposed on the base layer BS and cover the first conductive pattern CTL1. The first insulating layer TINS1 may include an inorganic insulating layer or an organic insulating layer.

A second conductive pattern CTL2 may be disposed on the first insulating layer TINS1. A second insulating layer TINS2 may be disposed on the first insulating layer TINS1 and cover the second conductive pattern CTL2. The second insulating layer TINS2 may include an organic insulating layer.

The first and second conductive patterns CTL1 and CTL2 may overlap the non-light-emitting region NPA. Although not illustrated, the first and second conductive patterns CTL1 and CTL2 may be disposed on the non-light-emitting region NPA between the light-emitting regions PA, and have a mesh shape.

The first and second conductive patterns CTL1 and CTL2 may provide sensors of the above-described input-sensing unit ISP. For example, the first and second conductive patterns CTL1 and CTL2 having a mesh shape may be spaced apart from each other in a predetermined region, and provide the sensors. A portion of the second conductive pattern CTL2 may be connected to the first conductive pattern CTL1.

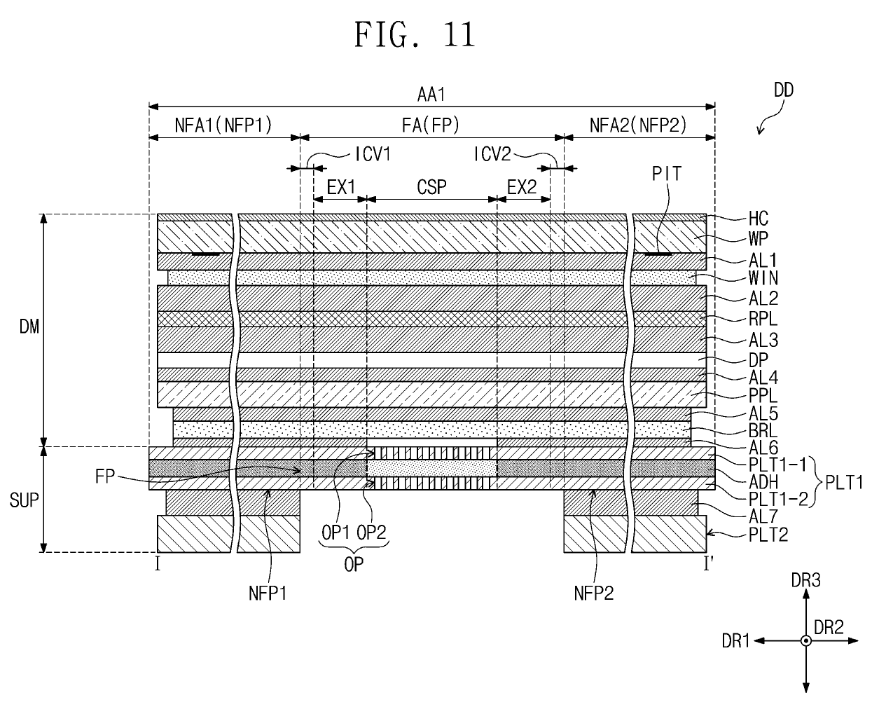

FIG. 11 is a cross-sectional view of a display device taken along line I-I' described in FIG. 8.

Referring to FIG. 11, a display device DD according to an embodiment of the inventive concept may include a display module DM and a support part SUP which is disposed below the display module DM and support the display module DM.

The display module DM may be a flexible display module. The display module DM may include a folding region FA and first and second non-folding regions NFA1 and NFA2 adjacent to the folding region FA, similar to the display panel DP. Accordingly, in the display module DM, the folding region FA may be disposed between the first non-folding region NFA1 and the second non-folding region NFA2, and the first non-folding region NFA1, the folding region FA, and the second non-folding region NFA2 may be arranged in the first direction DR1.

Hereinafter, the components of the display module DM and the support part SUP will be described in detail on the basis of the display device DD in a flat state.

The display module DM may include the display panel DP, an anti-reflection layer RPL, a window WIN, a window protective layer WP, a hard coating layer HC, a panel protective layer PPL, a barrier layer BRL, and first to sixth adhesive layers AL1 to AL6. The anti-reflection layer RPL, the window WIN, the window protective layer WP, and the hard coating layer HC may be disposed on the display panel DP. The panel protective layer PPL and the barrier layer BRL may be disposed below the display panel DP.

The anti-reflection layer RPL may be disposed on the display panel DP. The anti-reflection layer RPL may be defined as an external light anti-reflection film. The anti-reflection layer RPL may reduce reflectance for external light which enters the display panel DP from the outside.

When external light propagating toward the display panel DP is reflected at the display panel DP and is re-provided to an external user, the external light may be visible to a user as if reflected from a mirror. In order to prevent this phenomenon, the anti-reflection layer RPL may include, for example, a plurality of color filters which display colors same as those of pixels.

The color filters may filter the external light to display colors same as those of the pixels. In this case, the external light may be invisible to a user. However, embodiments of the present disclosure are not limited thereto, and the anti-reflection layer RPL may also include a retarder and/or a polarizer for reducing the reflectance for external light.

The window WIN may be disposed on the anti-reflection layer RPL. The window WIN may protect the display panel DP and the anti-reflection layer RPL from external scratches. The window WIN may have optically transparent properties. The window WIN may include glass. However, embodiments of the present disclosure are not limited thereto, and the window WIN may include a synthetic resin film.

The window WIN may have a multi-layered structure or a single-layered structure. For example, the window WIN may include a plurality of synthetic resin films bonded with an adhesive, or may include a glass substrate and a synthetic resin film bonded with an adhesive.

The window protective layer WP may be disposed on the window WIN. The window protective layer WP may include a flexible plastic material such as polyimide or polyethyleneterephthalate. A hard coating layer HC may be disposed on an upper surface of the window protective layer WP.

A printed layer PIT may be disposed on a lower surface of the window protective layer WP. The printed layer PIT may be black, but a color of the printed layer PIT is not limited thereto. The printed layer PIT may be adjacent to an edge of the window protective layer WP.

The first adhesive layer AL1 may be disposed between the window protective layer WP and the window WIN. The window protective layer WP and the window WIN may be bonded to each other via the first adhesive layer AL1. The first adhesive layer AL1 may cover the printed layer PIT from below the lower surface of the window protective layer WP.

The second adhesive layer AL2 may be disposed between the window WIN and the anti-reflection layer RPL. The window WIN and the anti-reflection layer RPL may be bonded to each other via the second adhesive layer AL2.

The third adhesive layer AL3 may be disposed between the anti-reflection layer RPL and the display panel DP. The anti-reflection layer RPL and the display panel DP may be bonded to each other via the third adhesive layer AL3.

The panel protective layer PPL may be disposed below the display panel DP. The panel protective layer PPL may protect a lower part of the display panel DP. The panel protective layer PPL may include a flexible plastic material. For example, the panel protective layer PPL may include polyethylene terephthalate (PET).

The barrier layer BRL may be disposed below the panel protective layer PPL. The barrier layer BRL may enhance resistance against a compressive force caused by external pressure. Accordingly, the barrier layer BRL may serve to prevent the display panel DP from being deformed. The barrier layer BRL may include a flexible plastic material such as polyimide or polyethyleneterephthalate.

The barrier layer BRL may have a color which absorbs light. The barrier layer BRL may be black. In this case, when the display module DM is viewed from above, components disposed below the barrier layer BRL may be invisible.

The fourth adhesive layer AL4 may be disposed between the display panel DP and the panel protective layer PPL. The display panel DP and the panel protective layer PPL may be bonded to each other via the fourth adhesive layer AL4.

The fifth adhesive layer AL5 may be disposed between the panel protective layer PPL and the barrier layer BRL. The panel protective layer PPL and the barrier layer BRL may be bonded to each other via the fifth adhesive layer AL5.

The sixth adhesive layer AL6 may be disposed below the barrier layer BRL. The sixth adhesive layer AL6 may be disposed between the barrier layer BRL and a first support plate PLT1 of the support part SUP. The barrier layer BRL and the first support plate PLT1 may be bonded to each other via the sixth adhesive layer AL6.

The first to sixth adhesive layers AL1 to AL6 may include a transparent adhesive such as a pressure sensitive adhesive (PSA) or an optically clear adhesive (OCA), but a type of adhesive is not limited thereto.

Hereinafter, in this specification, the term “thickness” may be defined as a numerical value measured in the third direction DR3. In this specification, the term "width" may be defined as a numerical value measured in a horizontal direction (for example, the first direction DR1 or the second direction DR2).

The thickness of the panel protective layer PPL may be smaller than the thickness of the window protective layer WP, the thickness of the anti-reflection layer RPL may be smaller than the thickness of the panel protective layer PPL, and the thickness of the display panel DP may be smaller than the thickness of the anti-reflection layer RPL. The thickness of the window WIN may be equal to the thickness of the anti-reflection layer RPL. The thickness of the barrier layer BRL may be smaller than the thickness of the panel protective layer PPL and greater than the thickness of the anti-reflection layer RPL.

The thickness of the first adhesive layer AL1 may be equal to the thickness of the barrier layer BRL, and the thickness of each of the second adhesive layer AL2 and the third adhesive layer AL3 may be equal to the thickness of the panel protective layer PPL. The thickness of each of the fourth adhesive layer AL4 and the fifth adhesive layer AL5 may be smaller than the thickness of the display panel DP. The fourth adhesive layer AL4 and the fifth adhesive layer AL5 may have the same thickness. The thickness of the sixth adhesive layer AL6 may be smaller than the thickness of each of the fourth adhesive layer AL4 and the fifth adhesive layer AL5, and the thickness of the hard coating layer HC may be smaller than the thickness of the sixth adhesive layer AL6.

The display panel DP, the anti-reflection layer RPL, the panel protective layer PPL, and the second to fourth adhesive layers AL2 to AL4 may have the same width. The window protective layer WP, the hard coating layer HC, and the first adhesive layer AL1 may have the same width.

The width of the window WIN may be smaller than the widths of the display panel DP, the anti-reflection layer RPL, the panel protective layer PPL, and the second to fourth adhesive layers AL2 to AL4. In some aspects, the width of the window WIN may be smaller than the widths of the window protective layer WP, the hard coating layer HC, and the first adhesive layer AL1.

When viewed on a plane, the edge of the window WIN may be disposed further inward than the edges of the display panel DP, the anti-reflection layer RPL, the panel protective layer PPL, and the second to fourth adhesive layers AL2 to AL4. In some aspects, when viewed on a plane, the edge of the window WIN may be disposed further inward than the edges of the window protective layer WP, the hard coating layer HC, and the first adhesive layer AL1.

When viewed on a plane, the barrier layer BRL and the fifth and sixth adhesive layers AL5 and AL6 may have the same width. When viewed on a plane, the edges of the barrier layer BRL and the fifth and sixth adhesive layers AL5 and AL6 may be disposed further inward than the edge of the window WIN.

The support part SUP may include the first support plate PLT1, a second support plate PLT2, and a seventh adhesive layer AL7. The first support plate PLT1 may be disposed below the display module DM and support the display module DM. The first support plate PLT1 may have a higher rigidity than the display module DM.

The first support plate PLT1 may include a metal material such as stainless steel. For example, the first support plate PLT1 may include SUS 304, but is not limited thereto. The first support plate PLT1 may include various metal materials. However, embodiments of the present disclosure are not limited thereto, and the first support plate PLT1 may also include a non-metallic material such as glass or plastic.

When viewed on a plane, the first support plate PLT1 may include a first non-folding part NFP1, a folding part FP, and a second non-folding part NFP2 which are arranged in the first direction DR1. The folding part FP may be disposed between the first non-folding part NFP1 and the second non-folding part NFP2. For example, the boundaries of the first non-folding part NFP1, the folding part FP, and the second non-folding part NFP2 are illustrated as dotted lines on the first support plate PLT1.

The first non-folding part NFP1 may be disposed below the first non-folding region NFA1, and overlap the first non-folding region NFA1. The second non-folding part NFP2 may be disposed below the second non-folding region NFA2, and overlap the second non-folding region NFA2. The folding part FP may be disposed below the folding region FA, and overlap the folding region FA. While the display device DD is folded, the folding part FP may be folded. The folding state of the folding part FP will be illustrated below in FIG. 15.

Openings OP overlapping the folding region FA may be defined in the first support plate PLT1. For example, the openings OP may be defined in the folding part FP.

The folding part FP may include a curved portion CSP, a first extension portion EX1, a second extension portion EX2, a first reverse curvature portion ICV1, and a second reverse curvature portion ICV2. For example, boundaries of the curved portion CSP, the first extension portion EX1, the second extension portion EX2, the first reverse curvature portion ICV1, and the second reverse curvature portion ICV2 are illustrated as dotted lines on the first support plate PLT1, and for convenience of description, boundary dotted lines are extended upward, and the reference numerals or symbols are denoted on an upper part of the display module DM.

The curved portion CSP, the first extension portion EX1, the second extension portion EX2, the first reverse curvature portion ICV1, and the second reverse curvature portion ICV2 may be arranged in the first direction DR1. For example, the curved portion CSP may be disposed at the center of the folding part FP.

The curved portion CSP may be disposed between the first extension portion EX1 and the second extension portion EX2. The openings OP may be defined in the curved portion CSP. As the openings OP are defined in the curved portion CSP, the curved portion CSP may have improved flexibility. In this case, when the folding part FP is folded, the curved portion CSP may be easily folded. The folding state of the curved portion CSP will be illustrated below in FIG. 15.

The first extension portion EX1 may be disposed between the first reverse curvature portion ICV1 and the curved portion CSP. The second extension portion EX2 may be disposed between the second reverse curvature portion ICV2 and the curved portion CSP. The first reverse curvature portion ICV1 may be disposed between the first extension portion EX1 and the first non-folding part NFP1. The second reverse curvature portion ICV2 may be disposed between the second extension portion EX2 and the second non-folding part NFP2.

The sixth adhesive layer AL6 may not overlap the curved portion CSP. That is, the sixth adhesive layer AL6 may be opened in a region overlapping the curved portion CSP.

On the basis of a stacked state, the first support plate PLT1 may include a (1-1)-th support plate PLT1-1, a (1-2)-th support plate PLT1-2, and an adhesive layer ADH. The (1-1)-th support plate PLT1-1 may be disposed below the display module DM, and the (1-2)-th support plate PLT1-2 may be disposed below the (1-1)-th support plate PLT1-1.

The adhesive layer ADH may be disposed between the (1-1)-th support plate PLT1-1 and the (1-2)-th support plate PLT1-2. The (1-1)-th support plate PLT1-1 and the (1-2)-th support plate PLT1-2 may be bonded to each other via the adhesive layer ADH.

The (1-1)-th support plate PLT1-1 may be disposed below the barrier layer BRL, and the sixth adhesive layer AL6 may be disposed between the (1-1)-th support plate PLT1-1 and the barrier layer BRL. The (1-1)-th support plate PLT1-1 and the barrier layer BRL may be bonded to each other via the sixth adhesive layer AL6.

First openings OP1 overlapping the folding region FA may be defined in the (1-1)-th support plate PLT1-1. Specifically, the first openings OP1 may be defined in the curved portion CSP of the (1-1)-th support plate PLT1-1. The first openings OP1 may be provided penetrating through portions of the curved portion CSP of the (1-1)-th support plate PLT1-1 in the third direction DR3.

Second openings OP2 overlapping the folding region FA may be defined in the (1-2)-th support plate PLT1-2. Specifically, the second openings OP2 may be defined in the curved portion CSP of the (1-2)-th support plate PLT1-2. The second openings OP2 may be provided penetrating through portions of the curved portion CSP of the (1-2)-th support plate PLT1-2 in the third direction DR3. The second openings OP2 may overlap the first openings OP1.

The adhesive layer ADH may cover the first openings OP1 and the second openings OP2. Foreign substances may be introduced through the second openings OP2 defined in the (1-2)-th support plate PLT1-2. Since the adhesive layer ADH covers the second openings OP2, foreign substances introduced through the second openings OP2 may be blocked by the adhesive layer ADH and be prevented from reaching the display module DM.

The above-described openings OP may include the first openings OP1 and the second openings OP2. The curved portion CSP of each of the (1-1)-th support plate PLT1-1 and the (1-2)-th support plate PLT1-2 may have improved flexibility due to the first openings OP1 and the second openings OP2.

The second support plate PLT2 may be disposed below the first support plate PLT1. The second support plate PLT2 may overlap the first non-folding part NFP1 and the second non-folding part NFP2, and may not overlap the folding part FP.

The second support plate PLT2 may have a higher rigidity than the display module DM. The second support plate PLT2 may include metal such as a copper and nickel alloy, but is not limited thereto, and the second support plate PLT2 may include various metal materials. The second support plate PLT2 may have a heat dissipation function.

The second support plate PLT2 may include a (2-1)-th support plate PLT2-1 and a (2-2)-th support plate PLT2-2 spaced apart from each other in the first direction DR1. The (2-1)-th support plate PLT2-1 may be disposed below the first non-folding part NFP1 and overlap the first non-folding part NFP1. The (2-2)-th support plate PLT2-2 may be disposed below the second non-folding part NFP2 and overlap the second non-folding part NFP2.

The (2-1)-th and (2-2)-th support plates PLT2-1 and PLT2-2 may complement the support function of the first support plate PLT1 which supports the display module DM. For example, the (2-1)-th support plate PLT2-1 may support the first non-folding region NFA1, and the (2-2)-th support plate PLT2-2 may support the second non-folding region NFA2.

The seventh adhesive layer AL7 may be disposed between the first non-folding part NFP1 and the (2-1)-th support plate PLT2-1, and between the second non-folding part NFP2 and the (2-2)-th support plate PLT2-2. The first and second non-folding parts NFP1 and NFP2, and the (2-1)-th and (2-2)-th support plates PLT2-1 and PLT2-2 may be bonded to each other via the seventh adhesive layer AL7. The seventh adhesive layer AL7 may include a pressure sensitive adhesive or an optically clear adhesive.

The thickness of the first support plate PLT1 may be greater than the thickness of the second support plate PLT2, and the thickness of the second support plate PLT2 may be greater than the thickness of the window protective layer WP. The thickness of the seventh adhesive layer AL7 may be equal to the thickness of the third adhesive layer AL3.

When viewed on a plane, the edge of the seventh adhesive layer AL7 may be disposed further inward than the edge of the first support plate PLT1. When viewed on a plane, the edge of the second support plate PLT2 may be disposed further inward than the edge of the first support plate PLT1.

FIG. 12 is a cross-sectional view taken along line II-II' described in FIG. 8.

Referring to FIG. 12, a first hole H1 and a second hole H2 may be defined in a support part SUP and a display module DM. When viewed on a plane, a light-blocking pattern LBP may be disposed around the first hole H1 and the second hole H2. The light-blocking pattern LBP and the printed layer PIT may be disposed at the same layer. That is, the light-blocking pattern LBP may be disposed on a lower surface of a window protective layer WP.

The first hole H1 may be defined ranging from a second support plate PLT2 to a second adhesive layer AL2. For example, the first hole H1 may be defined in the second support plate PLT2, a first support plate PLT1, a barrier layer BRL, a panel protective layer PPL, a display panel DP, an anti-reflection layer RPL, and second to seventh adhesive layers AL2 to AL7.

The second hole H2 may be defined ranging from the second support plate PLT2 to the fifth adhesive layer AL5. For example, the second hole H2 may be defined in the second support plate PLT2, the first support plate PLT1, the barrier layer BRL, and the fifth to seventh adhesive layer AL5 to AL7.

The above-described camera CM may be disposed inside the first hole H1. The above-described sensor SN may be disposed inside the second hole H2. Light signals may be provided to the camera CM and the sensor SN via the first and second holes H1 and H2.

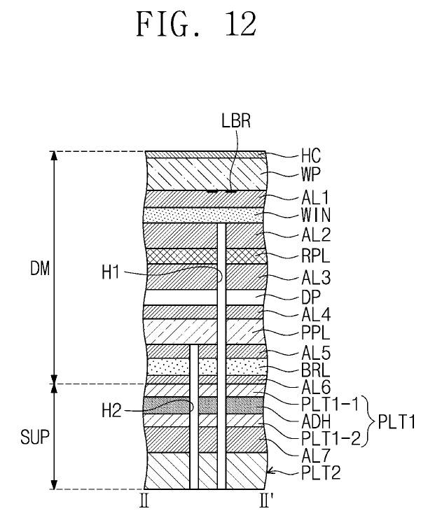

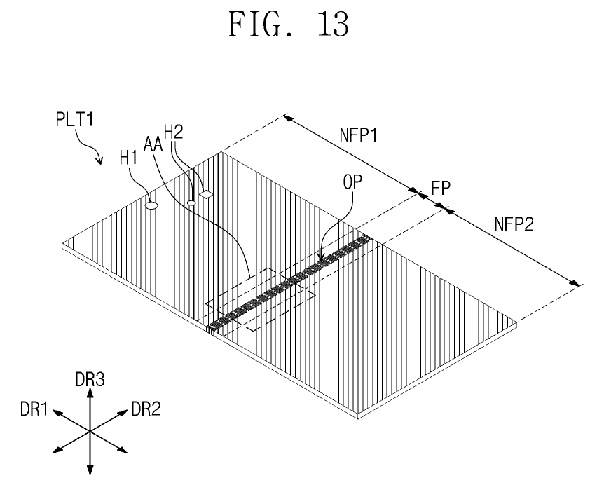

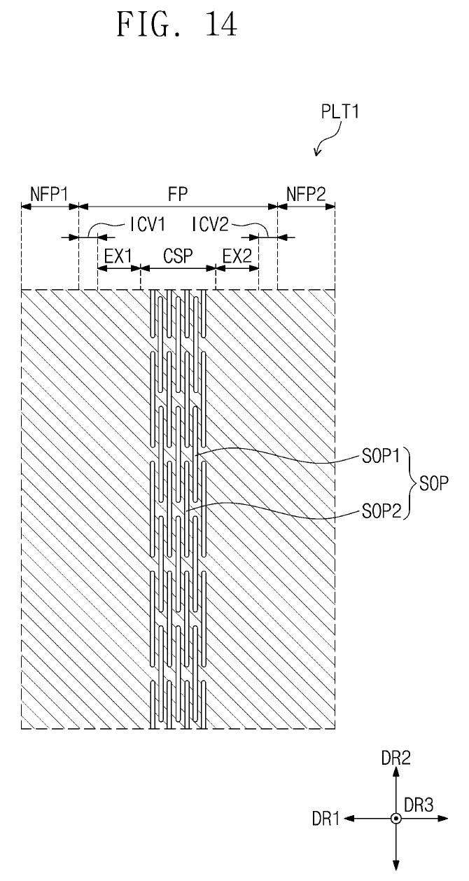

FIG. 13 is a perspective view of a support plate illustrated in FIG. 11. FIG. 14 is an enlarged plan view of a region AA illustrated in FIG. 13.

For example, in FIG. 13, a first support plate PLT1 is illustrated as a single layer, and the (1-1)-th support plate PLT1-1, the (1-2)-th support plate PLT1-2, and the adhesive layer ADH are omitted.

Referring to FIGS. 13 and 14, a lattice pattern may be provided on a curved portion CSP. For example, openings OP defined in the curved portion CSP may be arranged on the basis of a predetermined rule. The openings OP are arranged in a lattice shape, and thus a lattice pattern may be disposed on the curved portion CSP.

A first hole H1 and second holes H2 may be defined in a first non-folding part NFP1. The first hole H1 and the second holes H2 may be adjacent to an edge of the first non-folding part NFP1. The first hole H1 may correspond to the first hole H1 illustrated in FIG. 12, and the above-described camera CM may be disposed in the first hole H1. The second holes H2 may correspond to the second hole H2 illustrated in FIG. 12, and the above-described sensors SN may be disposed in the second holes H2.

The openings OP may extend longer in the second direction DR2 than in the first direction DR1. The openings OP may include a plurality of first sub-openings SOP1 which are arranged in the second direction DR2, and a plurality of second sub-openings SOP2 which are adjacent to the first sub-openings SOP1 in the first direction DR1 and are arranged in the second direction DR2. The first sub-openings SOP1 may be disposed offset from the second sub-openings SOP2.

FIG. 15 is a view illustrating a state in which the display device illustrated in FIG. 11 is folded.

FIG. 15 exemplarily illustrates a display module DM and a first support plate PLT1 as single layers. In FIG. 11, the openings OP are not defined in the adhesive layer ADH, but for convenience of description, FIG. 15 illustrates openings OP defined in the first support plate PLT1 to have a structure in which openings OP penetrate the first support plate PLT1. For convenience of description, in FIG. 15, the display module DM, the first support plate PLT1, and a second support plate PLT2 are illustrated, and the adhesive layers are omitted.

Referring to FIG. 15, the first support plate PLT1 may be folded with respect to a folding axis FX. The first support plate PLT1 may be folded in a dumbbell-like shape. As the first support plate PLT1 is folded, the display module DM may be folded with the first support plate PLT1.

A folding part FP is folded with respect to the folding axis FX, and thus the first support plate PLT1 may be folded. In an example in which the folding part FP is folded, a curved portion CSP may be bent to have a predetermined curvature. The openings OP are defined in the curved portion CSP, and thus the curved portion CSP may be more easily bent. The curved portion CSP may be bent to have a predetermined curvature radius Rc. As the folding part FP is folded, a folding region FA may be folded.

A first reverse curvature portion ICV1 may be bent in a direction opposite to a direction in which the curved portion CSP is bent. A second reverse curvature portion ICV2 may be bent in a direction opposite to a direction in which the curved portion CSP is bent. The second reverse curvature portion ICV2 may have a shape symmetrical with a shape of the first reverse curvature portion ICV1.

When the folding part FP is folded, first and second non-folding parts NFP1 and NFP2, and (2-1)-th and (2-2)-th support plates PLT2-1 and PLT2-2 may be maintained in a flat state. Accordingly, the first and second non-folding regions NFA1 and NFA2 may be maintained in a flat state due to the first and second non-folding parts NFP1 and NFP2, and the (2-1)-th and (2-2)-th support plates PLT2-1 and PLT2-2.

When the folding part FP is folded, the distance between the first non-folding part NFP1 and the second non-folding part NFP2 in the first direction DR1 may be smaller than the diameter of a circle having a curvature radius Rc. According to this structure, the first support plate PLT1 may be folded in a dumbbell-like shape.

FIG. 16 is a view illustrating a display module and a first support plate illustrated in FIG. 11.

For example, in FIG. 16, a display module DM is illustrated as a single layer, and the second support plate PLT2 and the adhesive layers are omitted.

Referring to FIG. 16, the thickness of a (1-1)-th support plate PLT1-1 may be equal to the thickness of a (1-2)-th support plate PLT1-2. The thickness of an adhesive layer ADH may be different from the thickness of the (1-1)-th support plate PLT1-1 and the thickness of the (1-2)-th support plate PLT1-2.

However, embodiments of the present disclosure are not limited thereto, and the thickness of the (1-1)-th support plate PLT1-1 may be different from the thickness of the (1-2)-th support plate PLT1-2. In some aspects, the thickness of the adhesive layer ADH may be equal to or different from the thickness of the (1-1)-th support plate PLT1-1, and the thickness of the (1-2)-th support plate PLT1-2. In some aspects, the respective thicknesses of the (1-1)-th support plate PLT1-1, the (1-2)-th support plate PLT1-2, and the adhesive layer ADH may be different from each other.

The (1-1)-th support plate PLT1-1 may have a thickness set to a ratio of about 10% to about 50% with respect to the total thickness of the first support plate PLT1. The adhesive layer ADH may have a thickness set to a ratio of about 10% to about 50% with respect to the total thickness of the first support plate PLT1. The (1-2)-th support plate PLT1-2 may have a thickness set to a ratio of about 10% to about 50% with respect to the total thickness of the first support plate PLT1.

Given that the sum of the ratios of the thickness of the (1-1)-th support plate PLT1-1, the thickness of the adhesive layer ADH, and the thickness of the (1-2)-th support plate PLT1-2 is 100%, the (1-1)-th support plate PLT1-1, the adhesive layer ADH, and the (1-2)-th support plate PLT1-2 may have thicknesses set to various ratios ranging within the above-described numerical %.

For example, the (1-1)-th support plate PLT1-1, the adhesive layer ADH, and the (1-2)-th support plate PLT1-2 may have thicknesses set to ratios of about 30%, about 40%, and about 30%, respectively. However, embodiments of the present disclosure are not limited thereto, and the (1-1)-th support plate PLT1-1, the adhesive layer ADH, and the (1-2)-th support plate PLT1-2 may have thicknesses set to about 35%, about 30%, and about 35%, respectively, thicknesses set to about 40%, about 20%, and about 40%, respectively, thicknesses set to about 45%, about 10%, and about 45%, respectively, thicknesses set to about 10%, about 40%, and about 50%, respectively, or thicknesses set to about 25%, about 50%, and about 25%, respectively.

Hereinafter, the first support plate, which has the same thickness as a thickness of the first support plate PLT1 and is formed only of SUS, is defined as a comparative support plate.

When the first support plate PLT1 includes the adhesive layer ADH which is lighter than stainless steel, the first support plate PLT1 may have a smaller weight than the comparative support plate.

In an embodiment of the inventive concept, the sum of the thicknesses of the (1-1)-th support plate PLT1-1 and the (1-2)-th support plate PLT1-2 may be set to about 40% to about 90% of the thickness of the first support plate PLT1. A density of the adhesive layer ADH may be about 1 g/cm³ to about 3 g/cm³, and preferably about 1.2 g/cm³.

In this case, the weight of the first support plate PLT1 may be reduced by about 30% or more compared to the weight of the comparative support plate. In this case, the first support plate PLT1 may have a rigidity at a level of about 90% or more with respect to the rigidity of the comparative support plate.

Portions, of the first support plate PLT1, having the rigidity at a level of about 90% or more with respect to the rigidity of the comparative support plate may be the first and second non-folding parts NFP1 and NFP2. Portions, of the first support plate PLT1, having a rigidity at a level of about 90% or more with respect to the rigidity of the comparative support plate may be the first and second reverse curvature portions ICV1 and ICV2, and the first and second extension portions EX1 and EX2. Due to the openings OP, the rigidity of the curved portion CSP may be lower than those of the first and second non-folding parts NFP1 and NFP2, the first and second reverse curvature portions ICV1 and ICV2, and the first and second extension portions EX1 and EX2.

When the (1-1)-th support plate PLT1-1, the adhesive layer ADH, and the (1-2)-th support plate PLT1-2 have thicknesses set to ratios of about 30%, about 40%, and about 30%, respectively, the weight of the first support plate PLT1 may be reduced by about 35% compared to the weight of the comparative support plate. In this case, the first support plate PLT1 may have a rigidity at a level of about 93% with respect to the rigidity of the comparative support plate.

The adhesive layer ADH may include a first adhesive layer ADH1 overlapping the folding region FA and second adhesive layers ADH2 respectively overlapping the first and second non-folding regions NFA1 and NFA2. For example, a boundary between the first adhesive layer ADH1 and the second adhesive layers ADH2 is illustrated as a thick dotted line.

Specifically, the first adhesive layer ADH1 may overlap the curved portion CSP. In some aspects, the second adhesive layers ADH2 may further overlap the first and second reverse curvature portions ICV1 and ICV2, and the first and second extension portions EX1 and EX2. The first adhesive layer ADH1 and the second adhesive layers ADH2 may be formed integrally without being physically spaced apart from each other.

Rigidities of the first adhesive layer ADH1 and the second adhesive layers ADH2 may be different from each other. For example, the first adhesive layer ADH1 may have a lower rigidity than the second adhesive layers ADH2. That is, the first adhesive layer ADH1 may be more easily bent than the second adhesive layers ADH2.

The first adhesive layer ADH1 may have a modulus which is smaller than respective moduli of the second adhesive layers ADH2, such that the first adhesive layer ADH1 has a lower rigidity than the second adhesive layers ADH2. For example, the first adhesive layer ADH1 may have a modulus of about 0.1 gigapascal (Gpa) to about 0.01 gigapascal (Gpa), and the second adhesive layers ADH2 may have a modulus of about 1 gigapascal (Gpa) to about 50 gigapascal (Gpa). The (1-1)-th support plate PLT1-1 and the (1-2)-th support plate PLT1-2 may each have a modulus of about 100 gigapascals (Gpa) to about 300 gigapascals (Gpa).

When the second adhesive layers ADH2 have the above-described modulus, the rigidities of the first and second non-folding parts NFP1 and NFP2 may be about 90% or more with respect to the rigidity of the comparative support plate. That is, the rigidity of the first support plate PLT1 may be maintained at a high level.

The first support plate PLT1 may maintain to have a high rigidity due to the second adhesive layers ADH2 which has a higher rigidity than the first adhesive layer ADH1, and the (1-1)-th support plate PLT1-1 and the (1-2)-th support plate PLT1-2 including metal. Therefore, the first support plate PLT1 may easily support the first and second non-folding regions NFA1 and NFA2. In some aspects, since the first support plate PLT1 includes the adhesive layer ADH which is lighter than metal, a reduction in a weight of the first support plate PLT1 may be achieved. In some aspects, the curved portion CSP of the first support plate PLT1 may be easily folded due to the first adhesive layer ADH1 which has a lower rigidity than the second adhesive layers ADH2.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be provided,” “may be prepared,” “may be performed,” “may be disposed,” “may be formed,” and the like include methods, processes, and techniques for providing, preparing, performing, disposing, forming, and the like in accordance with example aspects described herein.

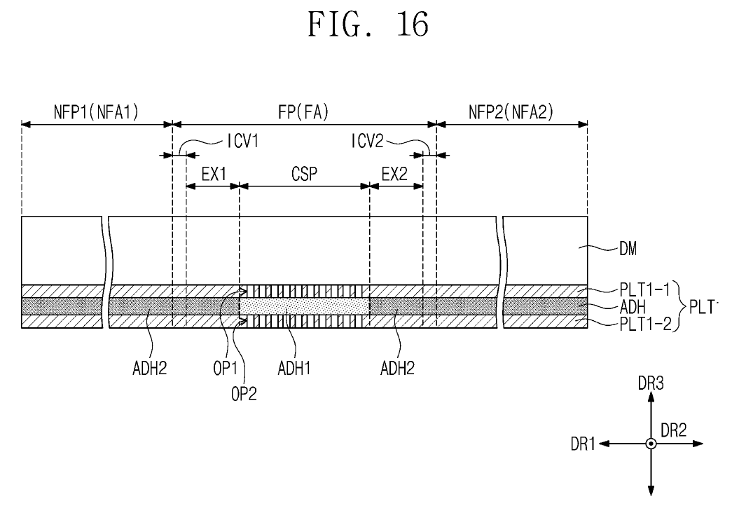

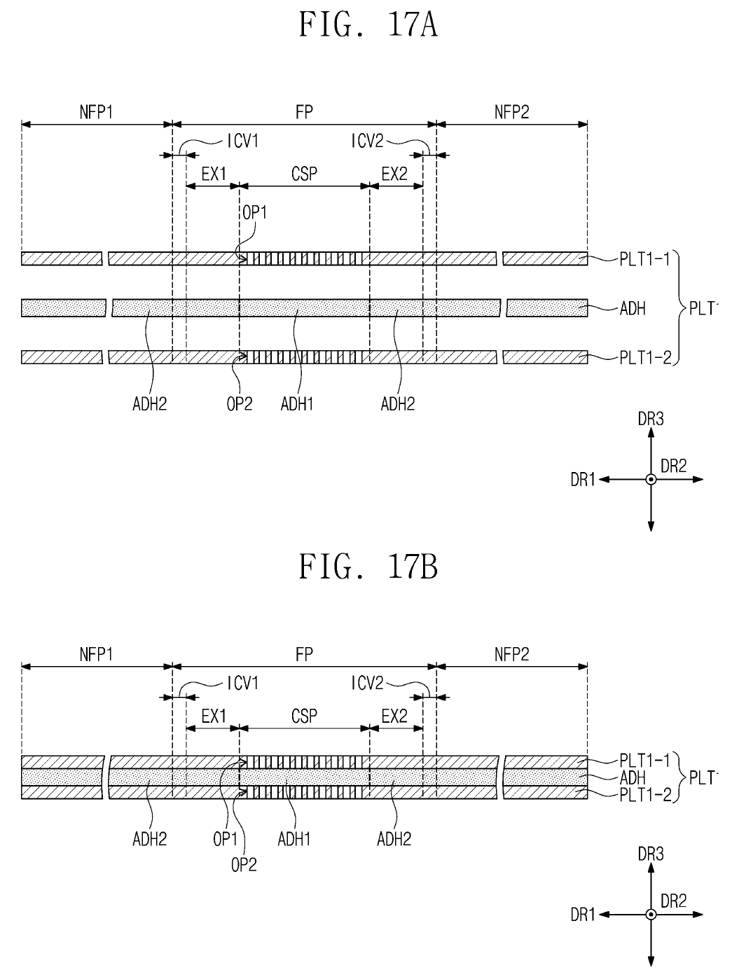

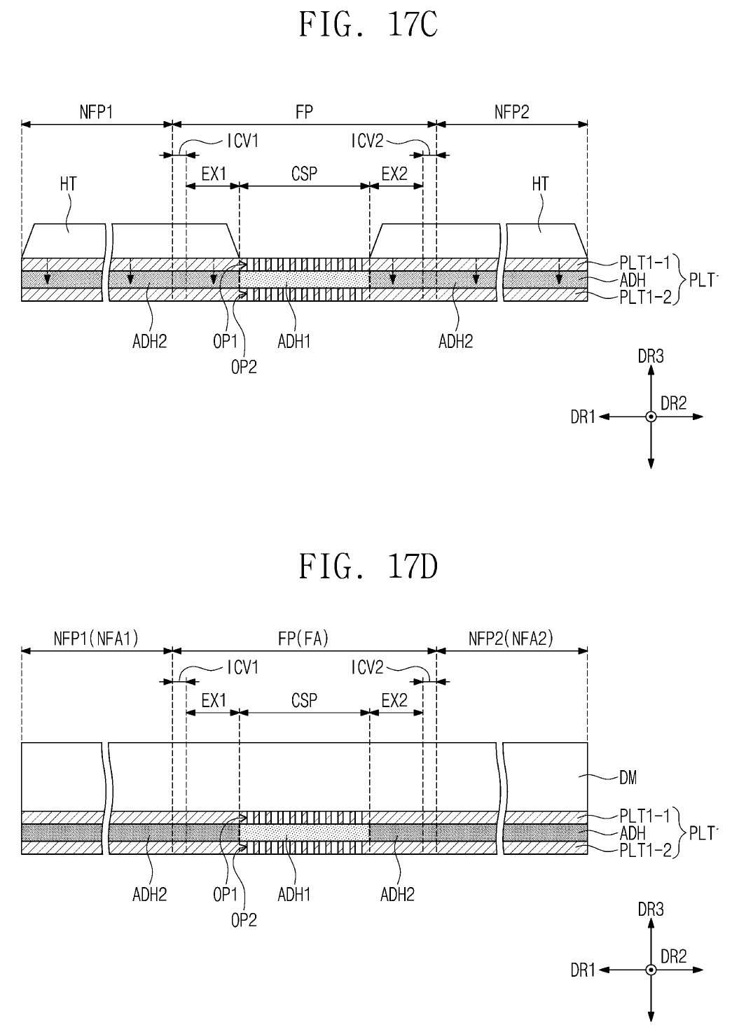

FIGS. 17A to 17D are views describing a method of manufacturing a display device according to an embodiment of the inventive concept.

FIGS. 17A to 17D are exemplarily illustrated as cross-sectional views corresponding to FIG. 16.

Referring to FIG. 17A, the method may include preparing a (1-1)-th support plate PLT1-1 and providing a (1-2)-th support plate PLT1-2 below the (1-1)-th support plate PLT1-1. The method may include providing an adhesive layer ADH between the (1-1)-th support plate PLT1-1 and the (1-2)-th support plate PLT1-2. Before a curing process of the adhesive layer ADH is performed, first and second adhesive layers ADH1 and ADH2 may have the same rigidity and modulus.

Referring to FIG. 17B, the method may include attaching the (1-1)-th support plate PLT1-1 and the (1-2)-th support plate PLT1-2 to the adhesive layer ADH.

Referring to FIG. 17C, the method may include performing a thermal curing process. According to the thermal curing process, the first adhesive layer ADH1 overlapping the first openings OP1 and the second openings OP2 may have a rigidity which is different from a rigidity of the second adhesive layer ADH2 not overlapping the first openings OP1 and the second openings OP2.

Specifically, heaters HT may be disposed on the second adhesive layers ADH2 and overlap the second adhesive layers ADH2. The heaters HT may be disposed on portions of the (1-1)-th support plate PLT1-1 which overlap the second adhesive layers ADH2. The heaters HT may be in contact with an upper surface of the (1-1)-th support plate PLT1-1. The heaters HT may be defined as a heat presser.

The heaters HT may exert a force against the (1-1)-th support plate PLT1-1, such that pressure is applied to the second adhesive layers ADH2. The heaters HT may apply heat to the second adhesive layers AHD2 via the (1-1)-th support plate PLT1-1.

The adhesive layer ADH may include a thermosetting resin, and the second adhesive layers AHD2 may be cured by heat (e.g., the heat applied by the heaters HT). The rigidities of the second adhesive layers ADH2 cured by heat may be higher than the rigidity of the first adhesive layer ADH1. Through the thermal curing process, the second adhesive layers ADH2 may have rigidities which are higher than a rigidity of the first adhesive layer ADH1, and the first adhesive layer ADH1 may have a rigidity which is lower than the rigidities of the second adhesive layers ADH2. Accordingly, the modulus of the first adhesive layer ADH1 may be smaller than the modulus of the second adhesive layers ADH2.

Referring to FIG. 17D, the method may include providing the display module DM on the first support plate PLT1, and the display device DD may thus be manufactured.

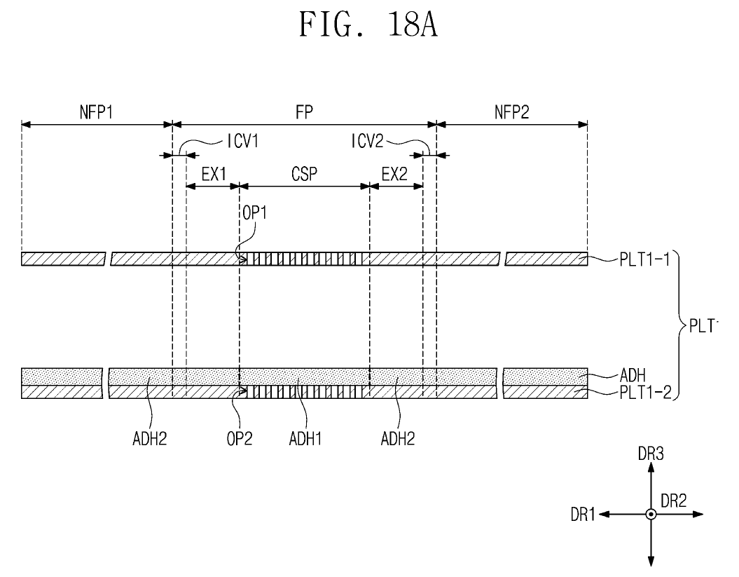

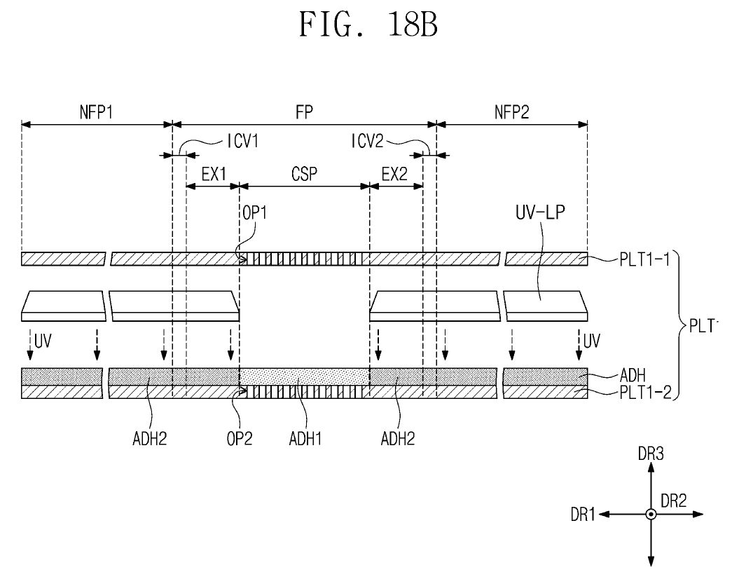

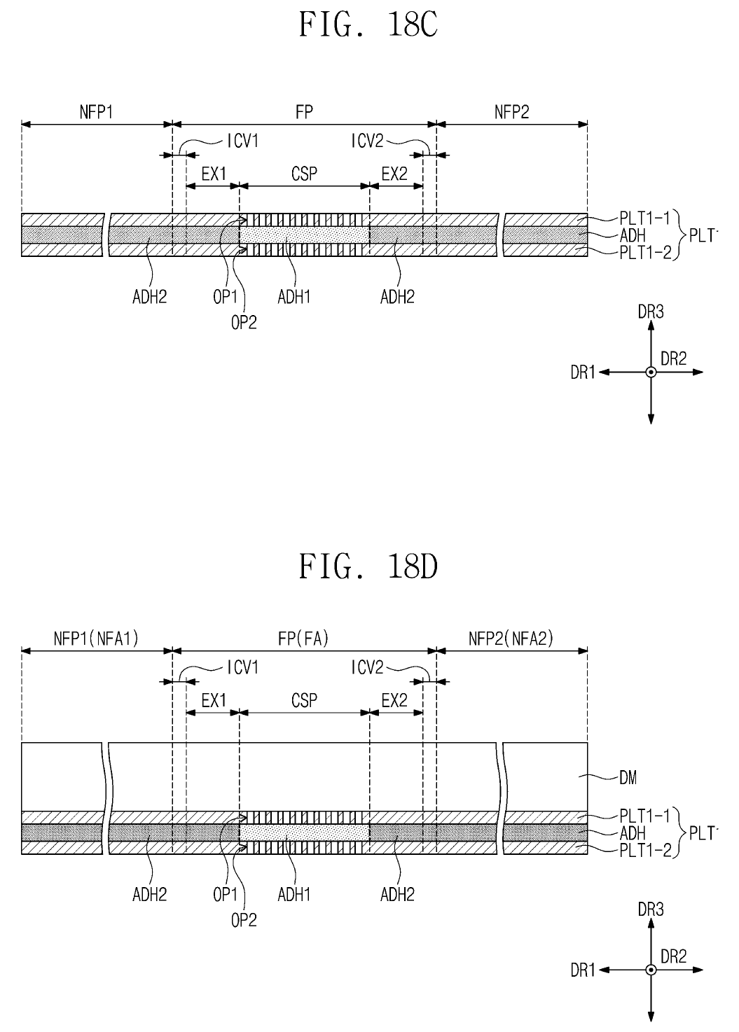

FIGS. 18A to 18D are views describing a method of manufacturing a display device according to another embodiment of the inventive concept.

FIGS. 18A to 18D are exemplarily illustrated as cross-sectional views corresponding to FIG. 16.

Referring to FIG. 18A, the method may include preparing a (1-1)-th support plate PLT1-1, providing a (1-2)-th support plate PLT1-2 below the (1-1)-th support plate PLT1-1, and providing an adhesive layer ADH between the (1-1)-th support plate PLT1-1 and the (1-2)-th support plate PLT1-2. The method may include attaching the adhesive layer ADH to an upper surface of the (1-2)-th support plate PLT1-2. The (1-1)-th support plate PLT1-1 may be spaced upward from the adhesive layer ADH.

Before the curing process of the adhesive layer ADH is performed, first and second adhesive layers ADH1 and ADH2 may have the same rigidity and modulus.

Referring to FIG. 18B, ultraviolet lamps UV-LP may be disposed between the (1-1)-th support plate PLT1-1 and the adhesive layer ADH. The ultraviolet lamps UV-LP may be disposed on the second adhesive layers ADH2, and overlap the second adhesive layers ADH2.

The method may include performing an ultraviolet curing process using the ultraviolet lamps UV-LP. Through the ultraviolet curing process, the first adhesive layer ADH1 may have a rigidity which is different from a rigidity of the second adhesive layer ADH2. Specifically, the adhesive layer ADH may include an ultraviolet curable resin, the method may include using the ultraviolet lamps UV-LP to irradiate the second adhesive layers ADH2 with ultraviolet rays UV, and the second adhesive layers AHD2 may be cured by the ultraviolet rays UV. The rigidities of the second adhesive layers ADH2 cured by the ultraviolet rays UV may be higher than the rigidity of the first adhesive layer ADH1.

Through the ultraviolet curing process, the second adhesive layers ADH2 may be formed to have rigidities which are higher than a rigidity of the first adhesive layer ADH1, and the first adhesive layer ADH1 may be formed to have a rigidity which is lower than rigidities of the second adhesive layers ADH2. Accordingly, the modulus of the first adhesive layer ADH1 may be smaller than the moduli of the second adhesive layers ADH2.

Referring to FIGS. 18C and 18D, the method may include attaching the (1-1)-th support plate PLT1-1 to the adhesive layer ADH and providing a display module DM on a first support plate PLT1, and a display device DD may thus be manufactured.

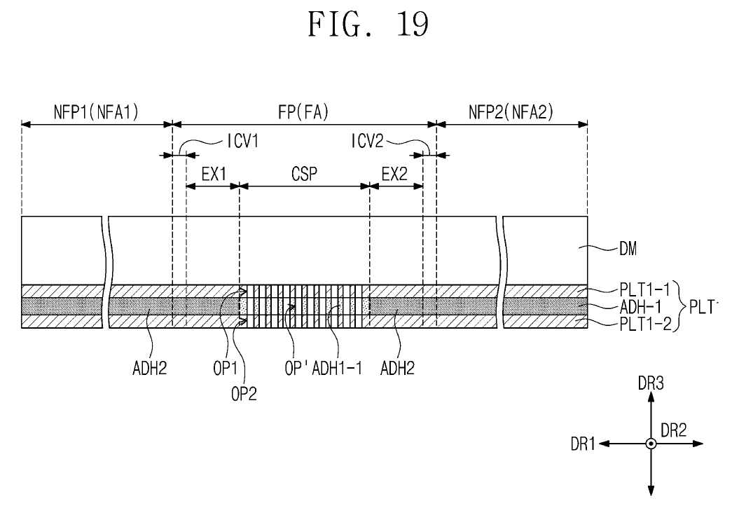

FIG. 19 is a view illustrating a configuration of a first adhesive layer according to another embodiment of the inventive concept.

FIG. 19 is exemplarily illustrated as a cross-sectional view corresponding to FIG. 16. Hereinafter, the description of a configuration illustrated in FIG. 19 will be mainly focused on components different from those illustrated in FIG. 16.

Referring to FIG. 19, openings OP’ which overlap first and second openings OP1 and OP2 may be defined in a first adhesive layer ADH1-1 of an adhesive layer ADH-1. The openings OP’ are defined in the first adhesive layer ADH1-1, and thus a curved portion CSP may be more easily bent.

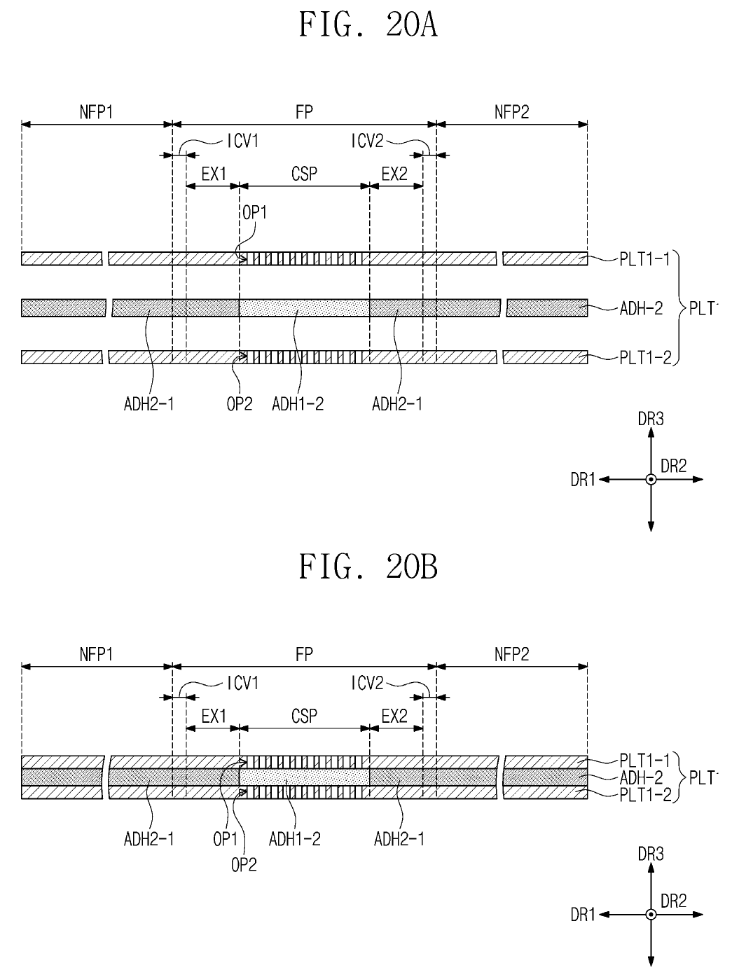

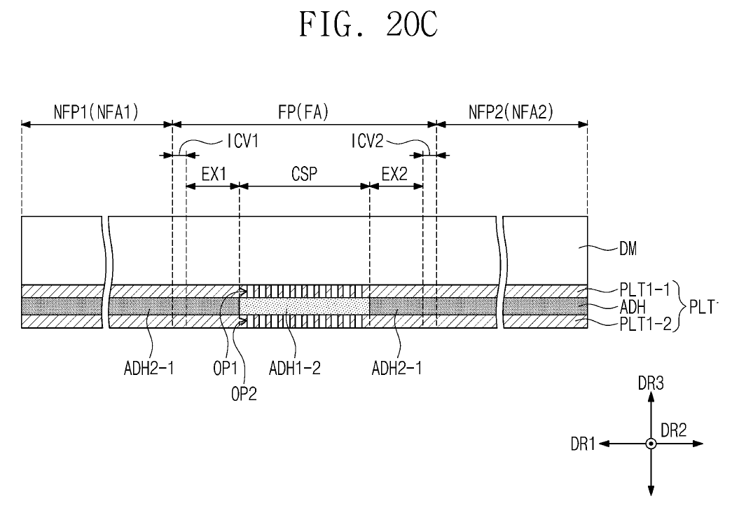

FIGS. 20A to 20C are views describing a method of manufacturing a display device according to another embodiment of the inventive concept.

FIGS. 20A to 20C are exemplarily illustrated as cross-sectional views corresponding to FIG. 16.

Referring to FIG. 20A, the method may include providing an adhesive layer ADH-2 between a (1-1)-th support plate PLT1-1 and a (1-2)-th support plate PLT1-2. The adhesive layer ADH-2 may include a first adhesive layer ADH1-2 and second adhesive layers ADH2-1 which are physically spaced apart from each other as well as are in contact with each other. Accordingly, a boundary between the first adhesive layer ADH1-2 and the second adhesive layers ADH2-1 is illustrated as a solid line. The first adhesive layer ADH1-2 and the second adhesive layers ADH2-1 may be provided between the (1-1)-th support plate PLT1-1 and the (1-2)-th support plate PLT1-2.

The strength (or the modulus) of the first adhesive layer ADH1-2 may be smaller than the strength (or the modulus) of the second adhesive layers ADH2-1. The first adhesive layer ADH1-2 and the second adhesive layers ADH2-1, which have different strengths before a curing process, may be provided between the (1-1)-th support plate PLT1-1 and the (1-2)-th support plate PLT1-2.

The first adhesive layer ADH1-2 and the second adhesive layers ADH2-1 may include different materials. For example, the first adhesive layer ADH1-2 may include an acrylic resin or a silicone resin, and the second adhesive layers ADH2-1 may include an epoxy resin.

Referring to FIG. 20B, the method may include attaching the (1-1)-th support plate PLT1-1 and the (1-2)-th support plate PLT1-2 to the adhesive layer ADH-2. The (1-1)-th support plate PLT1-1 and the (1-2)-th support plate PLT1-2 may be attached to the adhesive layer ADH-2 through a pressing process or a thermal pressing process.

Although not illustrated, a presser for the pressing process may be disposed on the (1-1)-th support plate PLT1-1 to pressurize the (1-1)-th support plate PLT1-1. Although not illustrated, according to another embodiment, a heat presser (for example, the heater HT illustrated in FIG. 17C) may be disposed on the (1-1)-th support plate PLT1-1, and the method may include applying pressure to the (1-1)-th support plate PLT1-1 and applying heat to the adhesive layer ADH-2, using the heat presser.

Referring to FIG. 20C, the method may include providing the display module DM on the first support plate PLT1, and thus the display device DD may be manufactured.

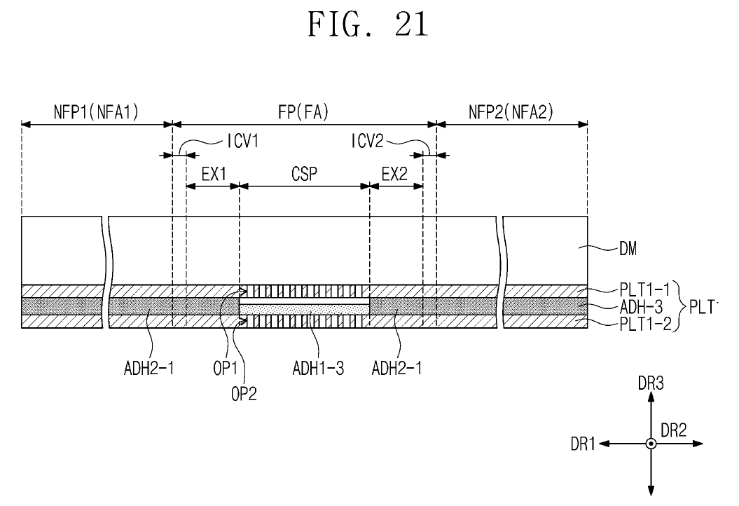

FIG. 21 is a view illustrating a configuration of an adhesive layer according to another embodiment of the inventive concept.

FIG. 21 is exemplarily illustrated as a cross-sectional view corresponding to FIG. 16. Hereinafter, the description of a configuration illustrated in FIG. 21 will be mainly focused on components different from those illustrated in FIG. 16.

Referring to FIG. 21, an adhesive layer ADH-3 may include a first adhesive layer ADH1-3 and second adhesive layers ADH2-1 which are spaced apart from each other such as the adhesive layer ADH-2 illustrated in FIG. 20A. The first adhesive layer ADH1-3 and the second adhesive layers ADH2-1 may be provided between a (1-1)-th support plate PLT1-1 and a (1-2)-th support plate PLT1-2.

The first adhesive layer ADH1-3 may be spaced apart from the (1-1)-th support plate PLT1-1 and be attached to an upper surface of the (1-2)-th support plate PLT1-2. The second adhesive layers ADH2-1 may be attached to the (1-1)-th support plate PLT1-1 and the (1-2)-th support plate PLT1-2.

The first adhesive layer ADH1-3 may have a smaller thickness than the second adhesive layers ADH2-1. The thickness of the first adhesive layer ADH1-3 is small, and thus a curved portion CSP on which the first adhesive layer ADH1-3 is disposed may be more easily bent.

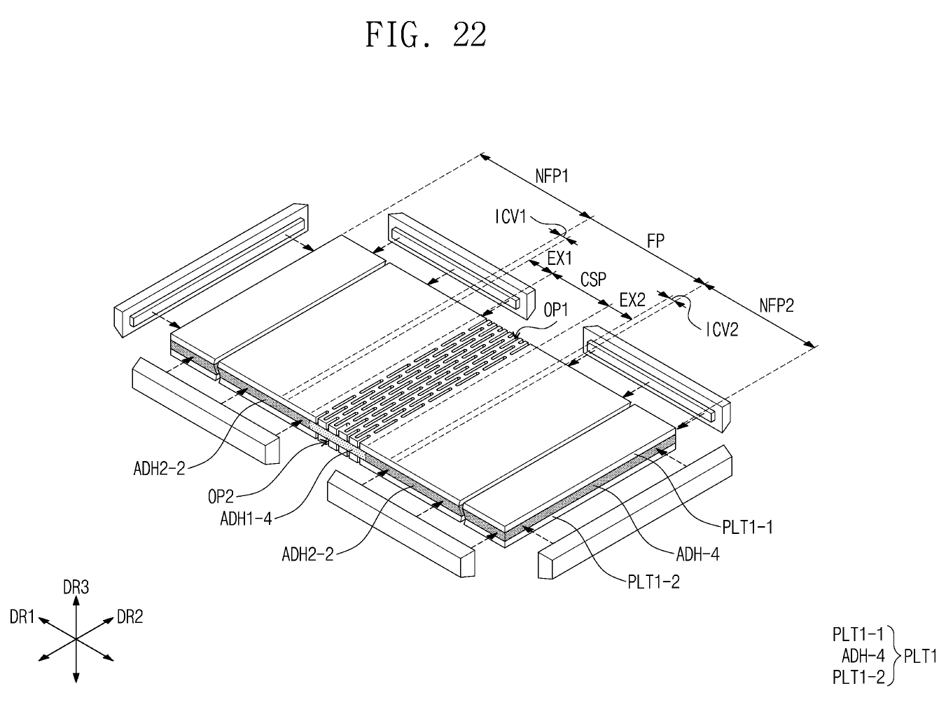

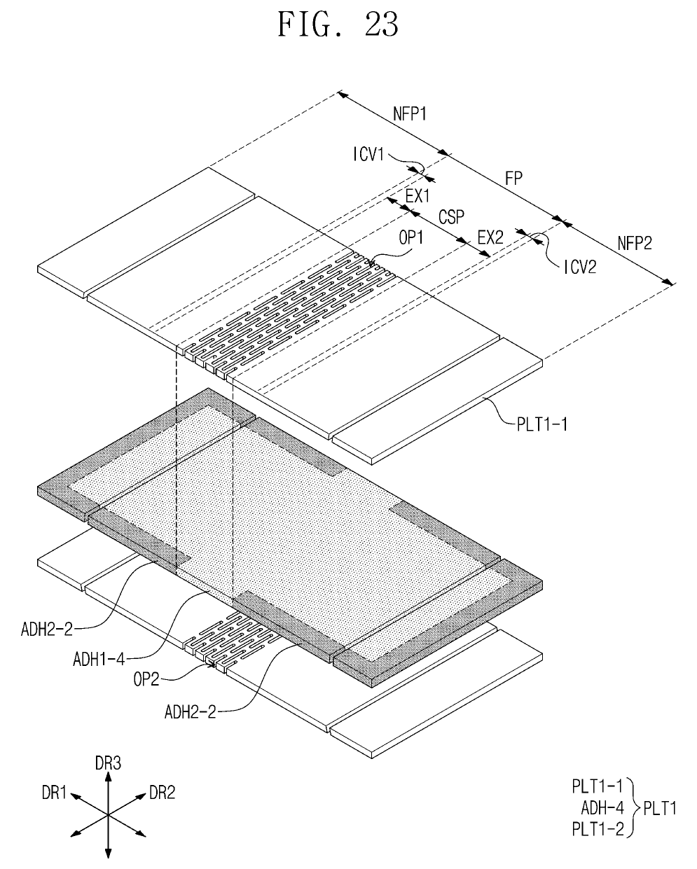

FIG. 22 is a view describing a curing process of an adhesive layer according to another embodiment of the inventive concept. FIG. 23 is an exploded view illustrating the (1-1)-th support plate, the (1-2)-th support plate, and the adhesive layer illustrated in FIG. 22.

For example, in FIGS. 21 and 22, the first support plate PLT1 is illustrated in a perspective view, and unlike the above-described manufacturing process, the display module DM is omitted.

Referring to FIG. 22, an adhesive layer ADH-4 may include a thermosetting resin and an ultraviolet curable resin. The adhesive layer ADH-4 may be provided between a (1-1)-th support plate PLT1-1 and a (1-2)-th support plate PLT1-2, and the (1-1)-th support plate PLT1-1 and the (1-2)-th support plate PLT1-2 may be attached to the adhesive layer ADH-4. The (1-1)-th support plate PLT1-1 and the (1-2)-th support plate PLT1-2 may be attached to the adhesive layer ADH-4 through the above-described thermal pressing process.

The adhesive layer ADH-4 may include a first adhesive layer ADH1-4 and second adhesive layers ADH2-2. After a thermal pressing process, ultraviolet lamps UV-LP may be disposed on edges of the second adhesive layers ADH2-2. The edges of the second adhesive layers ADH2-2 are irradiated with ultraviolet rays UV, and the second adhesive layers ADH2-2 may be cured. Thereafter, although not illustrated, a display module DM may be provided on the (1-1)-th support plate PLT1-1.

Referring to FIG. 23, the second adhesive layers ADH2-2 may be disposed adjacent to edges of first and second non-folding parts NFP1 and NFP2. Therefore, the second adhesive layers ADH2-2 may be substantially adjacent to the edges of the first and second non-folding regions NFA1 and NFA2 of the display module DM. In some aspects, the second adhesive layer ADH2-2 may be adjacent to edges of first and second reverse curvature portions ICV1 and ICV2, and first and second extension portions EX1 and EX2. The second adhesive layers ADH2-2 cured by the ultraviolet rays UV may have a higher rigidity (or a modulus) than the first adhesive layer ADH1-4.

According to an embodiment of the inventive concept, a support plate may include a (1-1)-th support plate in which first openings overlapping a folding region of a display module are defined, a (1-2)-th support plate in which second openings overlapping the folding region are defined, and an adhesive layer which is disposed between the (1-1)-th support plate and the (1-2)-th support plate. The adhesive layer includes a first adhesive layer overlapping the folding region, and a second adhesive layer overlapping a non-folding part of the display module adjacent to the folding region, and the first adhesive layer may have a lower rigidity than the second adhesive layer.

The support plate may have a high rigidity due to the (1-1)-th support plate and the (1-2)-th support plate which include metal and the second adhesive layer having a higher rigidity than the first adhesive layer, and a reduction in a weight of the support plate may be achieved by using the adhesive layer. In some aspects, a curved portion of the support plate overlapping the folding region may be easily folded due to the first adhesive layer which has a lower rigidity than the second adhesive layer.

In the above, description has been made with reference to embodiments of the inventive concept, but those skilled or of ordinary skill in the art may understand that various modifications and changes may be made to the inventive concept insofar as such modifications and changes do not depart from the spirit and technical scope of the inventive concept set forth in the claims to be described later.

Therefore, the technical scope of the inventive concept is not to be limited to the contents stated in the detailed description of the specification, but should be determined by the claims.

What is claimed is:

1. A display device comprising:
a display module comprising a folding region and a non-folding region adjacent to the folding region;
a (1-1)-th support plate which is disposed below the display module, and in which first openings overlapping the folding region are defined;
a (1-2)-th support plate which is disposed below the (1-1)-th support plate, and in which second openings overlapping the folding region are defined; and
an adhesive layer disposed between the (1-1)-th support plate and the (1-2)-th support plate,
wherein the adhesive layer comprises:
a first adhesive layer overlapping the folding region; and
a second adhesive layer overlapping the non-folding region and having a rigidity which is different from a rigidity of the first adhesive layer.

2. The display device of claim 1, wherein the rigidity of the first adhesive is lower than the rigidity of the second adhesive layer.

3. The display device of claim 1, wherein the first adhesive layer has a modulus which is smaller than a modulus of the second adhesive layer.

4. The display device of claim 1, wherein the adhesive layer comprises a thermosetting resin or an ultraviolet curable resin.

5. The display device of claim 1, wherein the first adhesive layer and the second adhesive layer are formed integrally.

6. The display device of claim 1, wherein:
a thickness of the (1-1)-th support plate is equal to a thickness of the (1-2)-th support plate, and
a thickness of the adhesive layer is different from each of the thickness of the (1-1)-th support plate and the thickness of the (1-2)-th support plate.

7. The display device of claim 1, wherein a thickness of the (1-1)-th support plate, a thickness of the (1-2)-th support plate, and a thickness of the adhesive layer are different from each other.

8. The display device of claim 1, wherein a sum of a thickness of the (1-1)-th support plate and a thickness of the (1-2)-th support plate is set to about 40% to about 90% of a thickness of a support plate which comprises the (1-1)-th support plate, the (1-2)-th support plate, and the adhesive layer.

9. The display device of claim 1, wherein the (1-1)-th support plate, the adhesive layer, and the (1-2)-th support plate have thicknesses set to ratios of about 30%, about 40%, and about 30%, respectively, with respect to a thickness of a support plate which comprises the (1-1)-th support plate, the adhesive layer, and the (1-2)-th support plate.

10. The display device of claim 1, wherein:
the first adhesive layer has a modulus of about 0.1 gigapascal to about 0.01 gigapascal, and
the second adhesive layer has a modulus of about 1 gigapascal to about 50 gigapascal.

11. The display device of claim 1, wherein openings overlapping the first openings and the second openings are defined in the first adhesive layer.

12. The display device of claim 1, wherein the first adhesive layer and the second adhesive layer are spaced apart from each other.

13. The display device of claim 1, wherein the first adhesive layer has a thickness which is smaller than a thickness of the second adhesive layer.

14. The display device of claim 1, wherein the second adhesive layer is adjacent to an edge of the non-folding region.

15. A method of manufacturing a display device, the method comprising:
preparing a (1-1)-th support plate in which first openings are defined;
providing, below the (1-1)-th support plate, a (1-2)-th support plate in which second openings overlapping the first openings are defined;
providing an adhesive layer between the (1-1)-th support plate and the (1-2)-th support plate;
forming a first adhesive layer overlapping the first openings and the second openings and a second adhesive layer not overlapping the first openings and the second openings, wherein:
each of the first adhesive layer and the second adhesive layer is defined as a respective portion of the adhesive layer, and
a rigidity of the first adhesive layer is different from a rigidity of the second adhesive layer; and
providing, on the (1-1)-th support plate, a display module which comprises:
a folding region overlapping the first adhesive layer; and
a non-folding region adjacent to the folding region and overlapping the second adhesive layer.

16. The method of claim 15, further comprising:
attaching the (1-1)-th support plate and the (1-2)-th support plate to the adhesive layer; and
applying heat to the second adhesive layer to such that the second adhesive layer to has a rigidity which is higher than a rigidity of the first adhesive layer,
wherein the adhesive layer further comprises a thermosetting resin.

17. The method of claim 15, further comprising:
attaching the adhesive layer to an upper surface of the (1-2)-th support plate;
irradiating the second adhesive layer with ultraviolet rays to such that the second adhesive layer to has a rigidity which is higher than a rigidity of the first adhesive layer; and
attaching the (1-1)-th support plate to the adhesive layer,
wherein the adhesive layer further comprises an ultraviolet curable resin.

18. The method of claim 15, further comprising:
attaching the (1-1)-th support plate and the (1-2)-th support plate to the adhesive layer; and
irradiating an edge of the second adhesive layer with ultraviolet rays to such that the second adhesive layer to has a rigidity which is higher than a rigidity of the first adhesive layer,
wherein the second adhesive layer is adjacent to an edge of the non-folding region.

19. The method of claim 15, wherein:
a sum of a thickness of the (1-1)-th support plate and a thickness of the (1-2)-th support plate is set to about 40% to about 90% of a thickness of a support plate which comprises the (1-1)-th support plate, the (1-2)-th support plate, and the adhesive layer,
the first adhesive layer has a modulus of about 0.1 gigapascal to about 0.01 gigapascal, and
the second adhesive layer has a modulus of about 1 gigapascal to about 50 gigapascal.

20. An electronic device comprising:
a processor; and
a display device which receives an image signal from the processor and provides, to a user, an image corresponding to the image signal,
wherein:
the display device comprises:
a display module comprising a folding region and a non-folding region adjacent to the folding region;
a (1-1)-th support plate which is disposed below the display module, and in which first openings overlapping the folding region are defined;
a (1-2)-th support plate which is disposed below the (1-1)-th support plate, and in which second openings overlapping the folding region are defined; and
an adhesive layer disposed between the (1-1)-th support plate and the (1-2)-th support plate, and
the adhesive layer comprises:
a first adhesive layer overlapping the folding region; and
a second adhesive layer overlapping the non-folding region, wherein the first adhesive layer has a modulus which is smaller than a modulus of the second adhesive layer.
